(19) United States
(12) Patent Application Publication
(10) Pub. No.: US 2025/0133738 A1
(43) Pub. Date: Apr. 24, 2025

(54) SEMICONDUCTOR DEVICE AND ELECTRONIC SYSTEM INCLUDING THE SAME

(71) Applicant: SAMSUNG ELECTRONICS CO., LTD., Suwon-si (KR)

(72) Inventors: Chulmin Choi, Suwon-si (KR); Changhee Lee, Suwon-si (KR); Dajin Kim, Suwon-si (KR); Jiwoong Kim, Suwon-si (KR); Tae Hun Kim, Suwon-si (KR); Sang-Yong Park, Suwon-si (KR); Seung Jae Baik, Suwon-si (KR); Gun-Wook Yoon, Suwon-si (KR); Jaeduk Lee, Suwon-si (KR)

(21) Appl. No.: 18/661,467

(22) Filed: May 10, 2024

(30) Foreign Application Priority Data
Oct. 19, 2023 (KR) 10-2023-0140716

(51) Int. Cl. H10B 43/27; H01L 25/065; H10B 41/10; H10B 41/27; H10B 41/35; H10B 41/41; H10B 43/10; H10B 43/35; H10B 43/40; H10B 80/00

(52) U.S. Cl. CPC H10B 43/27; H01L 25/0652; H10B 41/10; H10B 41/27; H10B 41/35; H10B 41/41; H10B 43/10; H10B 43/35; H10B 43/40; H10B 80/00; H01L 2225/06506

(57) ABSTRACT

A semiconductor device includes a gate stack with alternating conductive patterns and insulating patterns. The device also includes a first memory channel structure including a first channel layer enclosed by the gate stack and a first memory layer enclosing the first channel layer. The device also includes a source structure electrically connected to the first channel layer. The source structure includes several source layers stacked atop one another. The first channel layer is in physical contact with the second source layer but apart from the other source layers. The first source layer contains impurities of a first conductivity type. The second source layer is formed of an impurity-free material. The third source layer contains impurities of a second conductivity type different from the first conductivity type.

### CROSS-REFERENCE TO RELATED APPLICATION

This U.S. patent application claims priority under 35 U.S.C. § 119 to Korean Patent Application No. 10-2023-0140716, filed on Oct. 19, 2023, in the Korean Intellectual Property Office, the entire contents of which are hereby incorporated by reference.

### BACKGROUND

Due to their small-sized, multifunctional, and/or low-cost characteristics, semiconductor devices are being esteemed as important elements in the electronics industry. Semiconductor devices are classified into a semiconductor memory device for storing data, a semiconductor logic device for processing data, and a hybrid semiconductor device including both of memory and logic elements.

With the recent trend of high speed and low power consumption of electronic devices, semiconductor devices in electronic devices are also desired to have high operating speeds and/or low operating voltages. In order to achieve this, the integration density of the semiconductor devices can be increased. However, as the integration density of the semiconductor device increases, the semiconductor devices suffer from deteriorated electrical characteristics and low production yield. Accordingly, many studies are being conducted to improve the electrical characteristics and production yield of the semiconductor device.

### SUMMARY

This disclosure describes a semiconductor device with improved electrical and reliability characteristics and an electronic system including the same.

The present disclosure relates to a semiconductor device and an electronic system including the same, and in particular, to a semiconductor device including an impurity-free source layer and an electronic system including the same.

An example semiconductor device may include a gate stack with alternating conductive patterns and insulating patterns, a first memory channel structure including a first channel layer enclosed by the gate stack and a first memory layer enclosing the first channel layer, and a source structure electrically connected to the first channel layer. The source structure may include a first source layer on the gate stack, a second source layer on the first source layer, and a third source layer on the second source layer. The first channel layer may be spaced apart from the first and third source layers and may be in contact with the second source layer. The first source layer may contain impurities of a first conductivity type, and the second source layer may be formed of an impurity-free material. The third source layer may contain impurities of a second conductivity type that is different from the first conductivity type.

An example semiconductor device may include a gate stack with alternating conductive patterns and insulating patterns, a channel layer enclosed by the gate stack, a memory layer enclosing the channel layer, and a source structure electrically connected to the channel layer. The source structure may include a first source layer on the gate stack, a second source layer on the first source layer, and a third source layer on the second source layer. A level of a top surface of the memory layer may be lower than a level of a top surface of the first source layer and may be higher than a level of a bottom surface of the first source layer.

An example semiconductor device may include a main substrate, a semiconductor device on the main substrate, and a controller provided on the main substrate and electrically connected to the semiconductor device. The semiconductor device may include a peripheral circuit structure and a memory cell structure on the peripheral circuit structure. The memory cell structure may include a gate stack with alternating conductive patterns and insulating patterns, a channel layer penetrating the gate stack, a memory layer enclosing the channel layer, and a source structure on the gate stack. The source structure may include a first source layer on the gate stack, a second source layer on the first source layer, and a third source layer on the second source layer. The channel layer may be spaced apart from the first and third source layers and may be in contact with the second source layer. The second source layer may include an intervening portion interposed between the channel layer and the first source layer, and a thickness of the intervening portion may be smaller than a thickness of the first source layer.

### BRIEF DESCRIPTION OF THE DRAWINGS

FIG. 1A is an example schematic diagram illustrating an electronic system including a semiconductor device.

FIG. 1B is a perspective view schematically illustrating an example electronic system including a semiconductor device.

FIGS. 1C and 1D are sectional views schematically illustrating an example semiconductor package.

FIG. 2A is a plan view illustrating an example semiconductor device.

FIG. 2B is a sectional view taken along a line A-A′ of FIG. 2A.

FIG. 2C is an enlarged view illustrating a portion ‘E1’ of FIG. 2B.

FIG. 3 is an enlarged sectional view illustrating an example semiconductor device.

FIG. 4 is an enlarged sectional view illustrating an example semiconductor device.

FIG. 5 is an enlarged sectional view illustrating an example semiconductor device.

FIG. 6 is an enlarged sectional view illustrating an example semiconductor device.

FIG. 7 is a sectional view illustrating an example semiconductor device.

FIGS. 8A, 8B, 8C, 8D, 8E, and 8F are sectional views illustrating an example method of fabricating a semiconductor device.

FIG. 9 is a sectional view illustrating an example semiconductor device.

FIGS. 10A, 10B, 10C, 10D, 10E, 10F, and 10G are sectional views illustrating an example method of fabricating a semiconductor device.

FIG. 11A is a sectional view illustrating an example semiconductor device.

FIG. 11B is an enlarged view illustrating a portion ‘E2’ of FIG. 11A.

FIGS. 12A, 12B, 12C, and 12D are sectional views illustrating an example method of fabricating a semiconductor device.

FIG. 13 is a sectional view illustrating an example semiconductor device.

FIG. 14 is a sectional view illustrating an example method of fabricating a semiconductor device.

### DETAILED DESCRIPTION

Example embodiments of the inventive concepts will now be described more fully with reference to the accompanying drawings, in which example embodiments are shown.

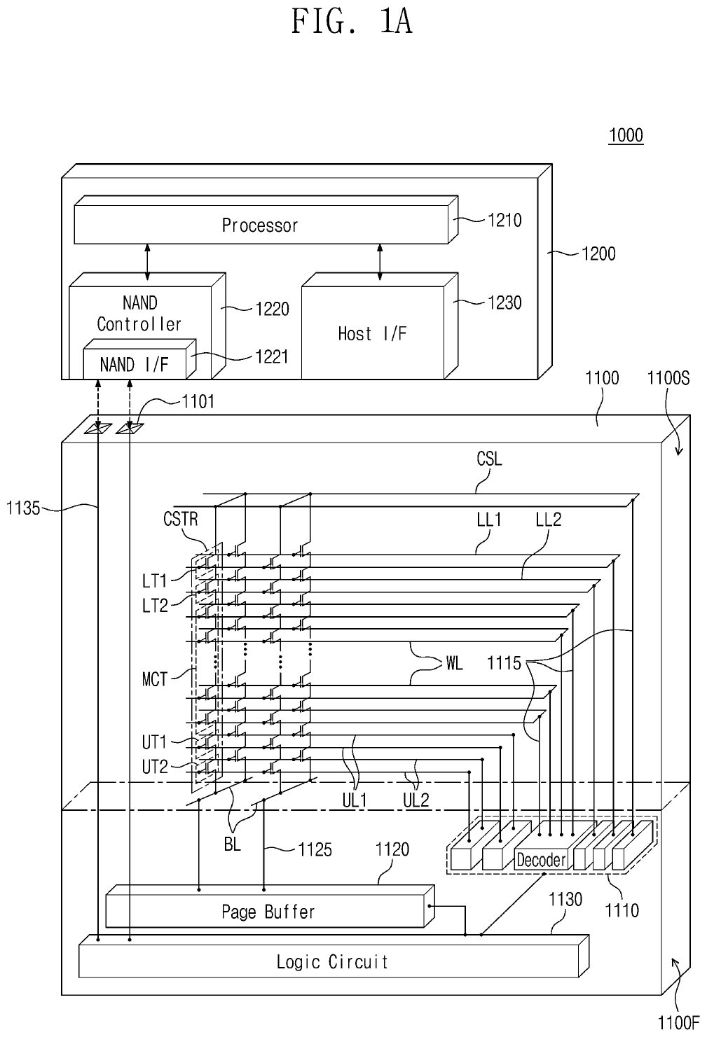

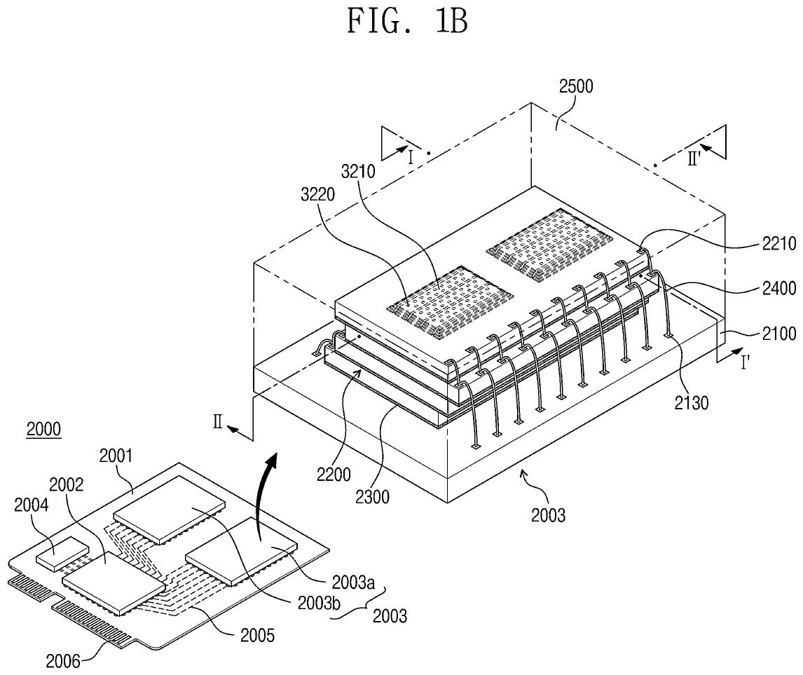

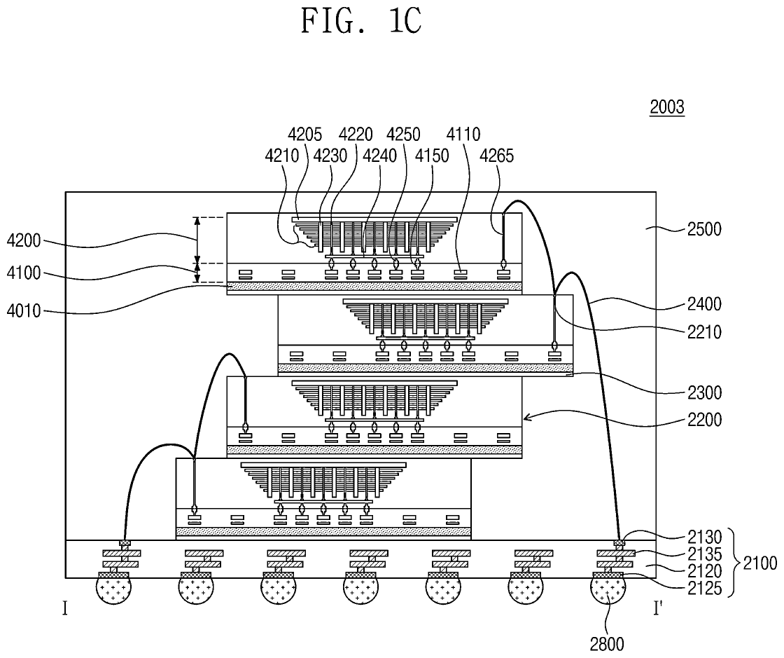

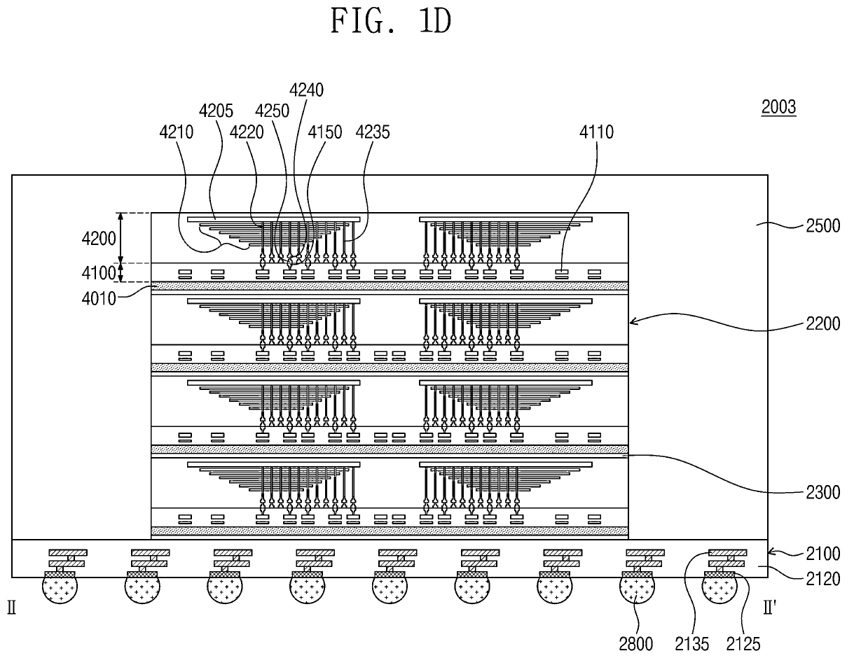

FIG. 1A is a diagram schematically illustrating an example electronic system including a three-dimensional semiconductor memory device.

Referring to FIG. 1A, an electronic system 1000 may include a three-dimensional semiconductor memory device 1100 and a controller 1200, which is electrically connected to the three-dimensional semiconductor memory device 1100. The electronic system 1000 may be a storage device including one or more three-dimensional semiconductor memory devices 1100 or an electronic device including the storage device. For example, the electronic system 1000 may be a solid state drive (SSD) device, a universal serial bus (USB), a computing system, a medical system, or a communication system, in which at least one three-dimensional semiconductor memory device 1100 is provided.

The three-dimensional semiconductor memory device 1100 may be a nonvolatile memory device (e.g., a three-dimensional NAND FLASH memory device to be described below). The three-dimensional semiconductor memory device 1100 may include a first region 1100F and a second region 1100S on the first region 1100F. However, unlike that illustrated in the drawings, the first region 1100F may be disposed beside the second region 1100S. The first region 1100F may be a peripheral circuit region, which includes a decoder circuit 1110, a page buffer 1120, and a logic circuit 1130. The second region 1100S may be a memory cell region, which includes bit lines BL, a common source line CSL, word lines WL, first lines LL1 and LL2, second lines UL1 and UL2, and memory cell strings CSTR between the bit lines BL and the common source line CSL.

In the second region 1100S, each of the memory cell strings CSTR may include first transistors LT1 and LT2 adjacent to the common source line CSL, second transistors UT1 and UT2 adjacent to the bit lines BL, and a plurality of memory cell transistors MCT disposed between the first transistors LT1 and LT2 and the second transistors UT1 and UT2. The number of the first transistors LT1 and LT2 and the number of the second transistors UT1 and UT2 may be variously changed, according to embodiments. The memory cell strings CSTR may be positioned between the common source line CSL and the first region 1100F.

For example, the second transistors UT1 and UT2 may include a string selection transistor, and the first transistors LT1 and LT2 may include a ground selection transistor. The first lines LL1 and LL2 may serve as gate electrodes of the first transistors LT1 and LT2. The word lines WL may serve as gate electrodes of the memory cell transistors MCT, and the second lines UL1 and UL2 may serve as gate electrodes of the second transistors UT1 and UT2.

For example, the first transistors LT1 and LT2 may include a first erase control transistor LT1 and a ground selection transistor LT2, which are connected in series. For example, the second transistors UT1 and UT2 may include a string selection transistor UT1 and a second erase control transistor UT2, which are connected in series. At least one of the first and second erase control transistors LT1 and UT2 may be used for an erase operation of erasing data, which are stored in the memory cell transistors MCT, using a gate-induced drain leakage (GIDL) phenomenon.

The common source line CSL, the first lines LL1 and LL2, the word lines WL, and the second lines UL1 and UL2 may be electrically connected to the decoder circuit 1110 through first interconnection lines 1115, which are extended from the first region 1100F to the second region 1100S. The bit lines BL may be electrically connected to the page buffer 1120 through second interconnection lines 1125, which are extended from the first region 1100F to the second region 1100S.

In the first region 1100F, the decoder circuit 1110 and the page buffer 1120 may be configured to perform a control operation, which is performed on at least one memory cell transistor that is selected from the memory cell transistors MCT. The decoder circuit 1110 and the page buffer 1120 may be controlled by the logic circuit 1130. The three-dimensional semiconductor memory device 1100 may communicate with the controller 1200 through an input/output pad 1101, which is electrically connected to the logic circuit 1130. The input/output pad 1101 may be electrically connected to the logic circuit 1130 through an input/output interconnection line 1135, which is extended from the first region 1100F to the second region 1100S.

The controller 1200 may include a processor 1210, a NAND controller 1220, and a host interface 1230. In an embodiment, the electronic system 1000 may include a plurality of three-dimensional semiconductor memory devices 1100, which are controlled by the controller 1200.

The processor 1210 may control overall operations of the electronic system 1000 including the controller 1200. Based on a specific firmware, the processor 1210 may execute operations of controlling the NAND controller 1220 and accessing the three-dimensional semiconductor memory device 1100. The NAND controller 1220 may include a NAND interface 1221, which is used for communication with the three-dimensional semiconductor memory device 1100. The NAND interface 1221 may be used to transmit and receive control commands to control the three-dimensional semiconductor memory device 1100, data to be written in or read from the memory cell transistors MCT of the three-dimensional semiconductor memory device 1100, and so forth. The host interface 1230 may be configured to allow for communication between the electronic system 1000 and an external host. If a control command is provided from an external host through the host interface 1230, the processor 1210 may control the three-dimensional semiconductor memory device 1100 in response to the control command.

FIG. 1B is a perspective view schematically illustrating an example electronic system including a three-dimensional semiconductor memory device.

Referring to FIG. 1B, an electronic system 2000 may include a main substrate 2001 and a controller 2002, one or more semiconductor packages 2003, and a DRAM 2004, which are mounted on the main substrate 2001. The semiconductor package 2003 and the DRAM 2004 may be connected to the controller 2002 and to each other by interconnection patterns 2005, which are provided in the main substrate 2001.

The main substrate 2001 may include a connector 2006, which includes a plurality of pins coupled to an external host. In the connector 2006, the number and the arrangement of the pins may be changed depending on a communication interface between the electronic system 2000 and an external host. For example, the electronic system 2000 may communicate with the external host, in accordance with one of the interfaces, such as universal serial bus (USB), peripheral component interconnect express (PCI-Express), serial advanced technology attachment (SATA), universal flash storage (UFS) M-PHY, or the like. In an embodiment, the electronic system 2000 may be driven by an electric power, which is supplied from the external host through the connector 2006. The electronic system 2000 may further include a power management integrated circuit (PMIC) that is used to separately supply the electric power, which is provided from the external host, to the controller 2002 and the semiconductor package 2003.

The controller 2002 may control a writing or reading operation on the semiconductor package 2003 and may improve an operation speed of the electronic system 2000.

The DRAM 2004 may be a buffer memory that is used to relieve technical difficulties caused by a difference in speed between the semiconductor package 2003, which serves as a data storage device, and an external host. In an embodiment, the DRAM 2004 in the electronic system 2000 may serve as a cache memory and may be used as a storage space, which is used to temporarily store data during a control operation on the semiconductor package 2003. In the case where the electronic system 2000 includes the DRAM 2004, the controller 2002 may further include a DRAM controller for controlling the DRAM 2004, in addition to a NAND controller for controlling the semiconductor package 2003.

The semiconductor package 2003 may include first and second semiconductor packages 2003a and 2003b, which are spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200, which are provided on the package substrate 2100, adhesive layers 2300, which are respectively disposed on bottom surfaces of the semiconductor chips 2200, connection structures 2400, which are used to electrically connect the semiconductor chips 2200 to the package substrate 2100, and a molding layer 2500, which is provided on the package substrate 2100 to cover the semiconductor chips 2200 and the connection structures 2400.

The package substrate 2100 may be a printed circuit board including package upper pads 2130. Each of the semiconductor chips 2200 may include input/output pads 2210. Each of the input/output pads 2210 may correspond to the input/output pad 1101 of FIG. 1A. Each of the semiconductor chips 2200 may include gate stacks 3210 and memory channel structures 3220. Each of the semiconductor chips 2200 may include a three-dimensional semiconductor memory device, which will be described below.

The connection structures 2400 may be, for example, bonding wires, which are used to electrically connect the input/output pads 2210 to the package upper pads 2130. That is, in each of the first and second semiconductor packages 2003a and 2003b, the semiconductor chips 2200 may be electrically connected to each other in a bonding wire manner and may be electrically connected to the package upper pads 2130 of the package substrate 2100. In an embodiment, the semiconductor chips 2200 in each of the first and second semiconductor packages 2003a and 2003b may be electrically connected by penetration electrodes (e.g., through silicon vias), not by a wire bonding method using the connection structures 2400.

Unlike the illustrated structure, the controller 2002 and the semiconductor chips 2200 may be included in a single package. In an embodiment, the controller 2002 and the semiconductor chips 2200 may be mounted on a separate interposer substrate, not on the main substrate 2001, and may be connected to each other through interconnection lines, which are provided in the interposer substrate.

FIGS. 1C and 1D are sectional views, which are respectively taken along lines I-I′ and II-II′ of FIG. 1B to illustrate an example semiconductor package including a three-dimensional semiconductor memory device.

Referring to FIGS. 1C and 1D, the semiconductor package 2003 may include the package substrate 2100, the semiconductor chips 2200 on the package substrate 2100, and the molding layer 2500 covering the package substrate 2100 and the semiconductor chips 2200.

The package substrate 2100 may include a package substrate body portion 2120, upper pads 2130, which are provided on a top surface of the package substrate body portion 2120 and are exposed to the outside of the package substrate body portion 2120 near the top surface, lower pads 2125, which are provided on a bottom surface of the package substrate body portion 2120 or are exposed to the outside of the package substrate body portion 2120 near the bottom surface, and internal lines 2135, which are provided in the package substrate body portion 2120 to electrically connect the upper pads 2130 to the lower pads 2125. The upper pads 2130 may be electrically connected to the connection structures 2400. The lower pads 2125 may be connected to the interconnection patterns 2005 of the main substrate 2001 of the electronic system 2000, which is shown in FIG. 1B, through conductive connecting portions 2800.

Referring to FIGS. 1B and 1C, the semiconductor chips 2200 may be provided to have side surfaces, which are not aligned to each other, and other side surfaces, which are aligned to each other. The semiconductor chips 2200 may be electrically connected to each other through the connection structures 2400, which are provided in the form of bonding wires. Each of the semiconductor chips 2200 may include substantially the same elements.

Each of the semiconductor chips 2200 may include a semiconductor substrate 4010, a first structure 4100 on the semiconductor substrate 4010, and a second structure 4200 on the first structure 4100. The second structure 4200 may be connected to the first structure 4100 in a wafer bonding manner.

The first structure 4100 may include peripheral circuit interconnection lines 4110 and first bonding pads 4150. The second structure 4200 may include a common source line 4205, a gate stack 4210, which is provided between the common source line 4205 and the first structure 4100, memory channel structures 4220 and separation structures 4230, which are provided to penetrate the gate stack 4210, and second bonding pads 4250, which are electrically and respectively connected to the memory channel structures 4220 and the word lines WL (e.g., see FIG. 1A) of the gate stack 4210. For example, the second bonding pads 4250 may be electrically and respectively connected to the memory channel structures 4220 and the word lines WL through bit lines 4240, which are electrically connected to the memory channel structures 4220, and gate interconnection lines 4235, which are electrically connected to the word lines WL. The first bonding pads 4150 of the first structure 4100 and the second bonding pads 4250 of the second structure 4200 may be in contact with each other and may be coupled to each other. The coupling portions between the first bonding pads 4150 and the second bonding pads 4250 may be formed of or include, for example, copper (Cu).

Each of the semiconductor chips 2200 may further include the input/output pad 2210 and an input/output interconnection line 4265 below the input/output pad 2210. The input/output interconnection line 4265 may be electrically connected to some of the second bonding pads 4250 and some of the peripheral circuit interconnection lines 4110.

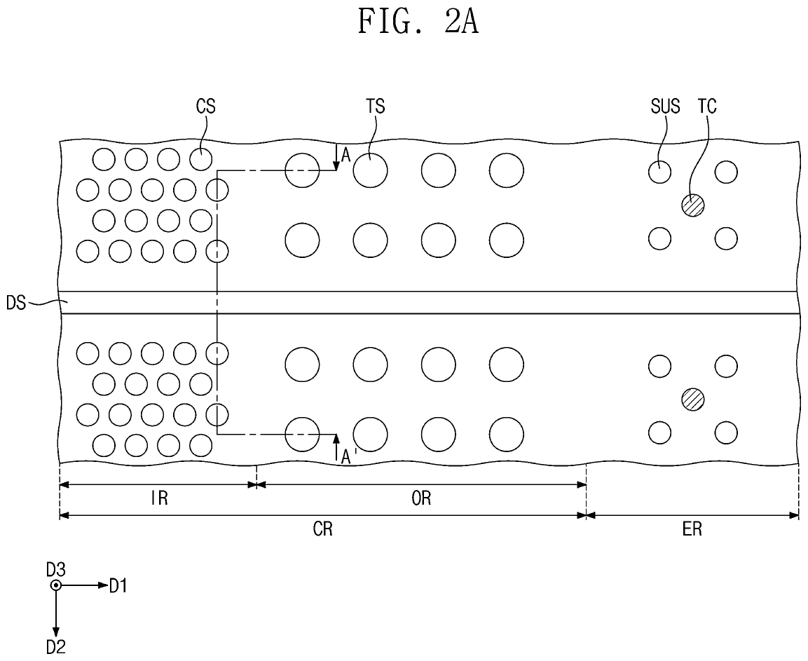

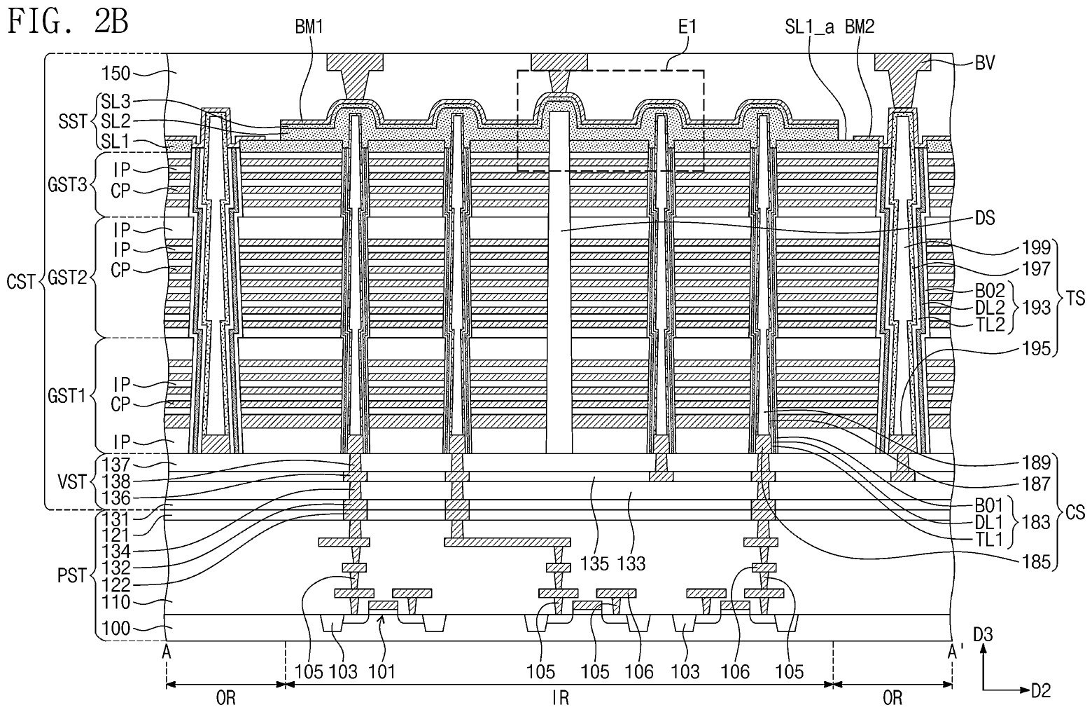

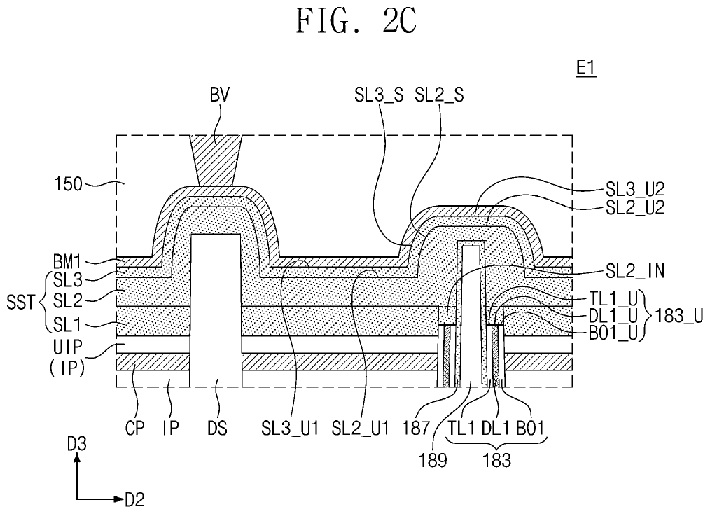

FIG. 2A is a plan view illustrating an example semiconductor device. FIG. 2B is a sectional view taken along a line A-A′ of FIG. 2A. FIG. 2C is an enlarged view illustrating a portion ‘E1’ of FIG. 2B.

Referring to FIGS. 2A, 2B, and 2C, the semiconductor device may include a peripheral circuit structure PST and a memory cell structure CST on the peripheral circuit structure PST.

The peripheral circuit structure PST may include a substrate 100. The substrate 100 may be a plate-shaped structure that is extended parallel to a plane defined by a first direction D1 and a second direction D2. The first and second directions D1 and D2 may not be parallel to each other. As an example, the first and second directions D1 and D2 may be horizontal directions that are orthogonal to each other. In an embodiment, the substrate 100 may be a semiconductor substrate, an insulating substrate, a silicon-on-insulator (SOI) substrate, or a germanium-on-insulator (GOI) substrate. The semiconductor substrate may be formed of or include at least one of silicon, germanium, silicon-germanium, GaP, or GaAs.

The peripheral circuit structure PST may further include a peripheral circuit insulating layer 110 on the substrate 100. The peripheral circuit insulating layer 110 may include an insulating material. In an embodiment, the peripheral circuit insulating layer 110 may be a multi-layered structure including a plurality of insulating layers.

The peripheral circuit structure PST may further include peripheral transistors 101. The peripheral transistors 101 may be provided between the substrate 100 and the peripheral circuit insulating layer 110. In an embodiment, the peripheral transistor 101 may include source/drain regions, a gate electrode, and a gate insulating layer. Device isolation layers 103 may be provided in the substrate 100. The peripheral transistors 101 may be disposed between the device isolation layers 103. The device isolation layer 103 may include an insulating material. In an embodiment, the device isolation layer 103 may be a multi-layered structure including a plurality of insulating layers.

The peripheral circuit structure PST may include peripheral contacts 105 and peripheral conductive lines 106. The peripheral contacts 105 and the peripheral conductive lines 106 may be electrically connected to the peripheral transistor 101. The peripheral contacts 105 and the peripheral conductive lines 106 may be provided in the peripheral circuit insulating layer 110. The peripheral contacts 105 and the peripheral conductive lines 106 may include a conductive material.

The peripheral circuit structure PST may further include a first bonding insulating layer 121. The first bonding insulating layer 121 may be provided on the peripheral circuit insulating layer 110. The first bonding insulating layer 121 may include an insulating material. In an embodiment, the first bonding insulating layer 121 may be a multi-layered structure including a plurality of insulating layers.

The peripheral circuit structure PST may further include first bonding pads 122. The first bonding pad 122 may be provided on the peripheral contact 105. The first bonding pad 122 may be electrically connected to the peripheral transistor 101 through the peripheral contact 105 and the peripheral conductive line 106. The first bonding pads 122 may be provided in the first bonding insulating layer 121. The first bonding pads 122 may include a conductive material.

The peripheral circuit structure PST may include a cell array region CR and an extension region ER. The cell array region CR may include a first cell region IR and a second cell region OR. The second cell region OR may be provided between the first cell region IR and the extension region ER. The first cell region IR, the second cell region OR, and the extension region ER may be defined based on a plan view taken parallel to the first and second directions D1 and D2.

The memory cell structure CST may include a lower interconnection structure VST, a first gate stack GST1, a second gate stack GST2, a third gate stack GST3, first memory channel structures CS, second memory channel structures TS, a division structure DS, supporting structures SUS, penetration contacts TC, a source structure SST, a first barrier layer BM1, a second barrier layer BM2, via structures BV, and a cover insulating layer 150.

The lower interconnection structure VST may be provided on the first bonding insulating layer 121. The lower interconnection structure VST may include a second bonding insulating layer 131, second bonding pads 132, a first interlayer insulating layer 133, connection contacts 134, a second interlayer insulating layer 135, bit lines 136, a third interlayer insulating layer 137, and bit line contacts 138.

The second bonding insulating layer 131 may be provided on the first bonding insulating layer 121. The second bonding insulating layer 131 may include an insulating material. In an embodiment, the second bonding insulating layer 131 may include the same insulating material as the first bonding insulating layer 121. In an embodiment, the second bonding insulating layer 131 may be a multi-layered structure including a plurality of insulating layers.

The second bonding pad 132 may be provided on the first bonding pad 122. The second bonding pads 132 may be provided in the second bonding insulating layer 131. The second bonding pads 132 may include a conductive material.

The second bonding insulating layer 131 may be bonded to the first bonding insulating layer 121 through a wafer bonding process. The second bonding pad 132 may be bonded to the first bonding pad 122 through the wafer bonding process. The peripheral circuit structure PST and the memory cell structure CST may form a hybrid bonding structure.

The first interlayer insulating layer 133 may be provided on the second bonding insulating layer 131. The first interlayer insulating layer 133 may include an insulating material. In an embodiment, the first interlayer insulating layer 133 may be a multi-layered structure including a plurality of insulating layers.

The connection contact 134 may be provided on the second bonding pad 132. The connection contact 134 may be provided in the first interlayer insulating layer 133. The connection contact 134 may include a conductive material.

The second interlayer insulating layer 135 may be provided on the first interlayer insulating layer 133. The second interlayer insulating layer 135 may include an insulating material. In an embodiment, the second interlayer insulating layer 135 may be a multi-layered structure including a plurality of insulating layers.

The bit line 136 may be provided on the connection contact 134. The bit lines 136 may be provided in the second interlayer insulating layer 135. The bit lines 136 may be extended in the first direction D1. The bit lines 136 may be arranged in the second direction D2. The bit lines 136 may include a conductive material.

The third interlayer insulating layer 137 may be provided on the second interlayer insulating layer 135. The third interlayer insulating layer 137 may include an insulating material. In an embodiment, the third interlayer insulating layer 137 may be a multi-layered structure including a plurality of insulating layers.

The bit line contact 138 may be provided on the bit line 136. The bit line contacts 138 may be provided in the third interlayer insulating layer 137. The bit line contacts 138 may include a conductive material.

The number of the interlayer insulating layers 133, 135, and 137 may not be limited to the number in the illustrated example. In an embodiment, the number of the interlayer insulating layers 133, 135, and 137 may be equal to or less than 2 or may be equal to or greater than 4. In an embodiment, a plurality of conductive structures may be provided to electrically connect the bit line 136 to the second bonding pad 132, instead of the connection contact 134.

The first gate stack GST1 may be provided on the third interlayer insulating layer 137. The second gate stack GST2 may be provided on the first gate stack GST1. The third gate stack GST3 may be provided on the second gate stack GST2. The number of the gate stacks GST1, GST2, and GST3 may not be limited to the number in the illustrated example. In an embodiment, the number of the gate stacks GST1, GST2, and GST3 may be equal to or less than 2 or may be equal to or greater than 4.

Each of the first to third gate stacks GST1, GST2, and GST3 may include insulating patterns IP and conductive patterns CP, which are alternately stacked in a third direction D3. The third direction D3 may not be parallel to the first and second directions D1 and D2. As an example, the third direction D3 may be a vertical direction that is orthogonal to the first and second directions D1 and D2. The insulating patterns IP may include an insulating material. As an example, the insulating patterns IP may be formed of or include at least one of oxide material or low-k dielectric materials, but is not limited to this example. The conductive patterns CP may include a conductive material. As an example, the conductive patterns CP may be formed of or include at least one of doped semiconductor materials, metallic materials, conductive metal nitride materials, or transition metal materials, but is not limited to this example.

Hereinafter, the uppermost one of the insulating patterns IP of the third gate stack GST3 may be referred to as an upper insulating pattern UIP. The upper insulating pattern UIP may be in contact with the source structure SST.

The first memory channel structures CS may be provided on the first cell region IR. The first memory channel structures CS may be extended in the third direction D3 to penetrate the first gate stack GST1, the second gate stack GST2, and the third gate stack GST3. Each of the memory channel structures CS may include a first insulating capping layer 189, a first channel layer 187 enclosing the first insulating capping layer 189, and a first memory layer 183 enclosing the first channel layer 187. The first insulating capping layer 189 and the first channel layer 187 may be provided to penetrate the first gate stack GST1, the second gate stack GST2, and the third gate stack GST3. The first insulating capping layer 189, the first channel layer 187, and the first memory layer 183 may be enclosed by the first to third gate stacks GST1, GST2, and GST3.

The second memory channel structures TS may be provided on the second cell region OR. The second memory channel structures TS may extend in the third direction D3 to penetrate the first gate stack GST1, the second gate stack GST2, and the third gate stack GST3. Each of the memory channel structures TS may include a second insulating capping layer 199, a second channel layer 197 enclosing the second insulating capping layer 199, and a second memory layer 193 enclosing the second channel layer 197. The second insulating capping layer 199 and the second channel layer 197 may be provided to penetrate the first gate stack GST1, the second gate stack GST2, and the third gate stack GST3. The second insulating capping layer 199, the second channel layer 197, and the second memory layer 193 may be enclosed by the first to third gate stacks GST1, GST2, and GST3. A width of the second memory channel structure TS in the first direction D1 may be larger than a width of the first memory channel structure CS in the first direction D1.

The first and second insulating capping layers 189 and 199 may include an insulating material. As an example, the first and second insulating capping layers 189 and 199 may be formed of or include an oxide material, but is not limited to this example. For example, at least one of the first and second channel layers 187 and 197 may include a conductive material. For example, the first and second channel layers 187 and 197 may be formed of or include poly silicon, but is not limited to this example.

The first and second memory layers 183 and 193 may be configured to store data. The first memory layer 183 may include a first tunnel insulating layer TL1 enclosing the first channel layer 187, a first data storing layer DL1 enclosing the first tunnel insulating layer TL1, and a first blocking layer BO1 enclosing the first data storing layer DL1. The second memory layer 193 may include a second tunnel insulating layer TL2 enclosing the second channel layer 197, a second data storing layer DL2 enclosing the second tunnel insulating layer TL2, and a second blocking layer BO2 enclosing the second data storing layer DL2.

In an implementation, the first and second tunnel insulating layers TL1 and TL2 may be formed of or include at least one of oxide materials (e.g., SiO, AlO, or HfO), but is not limited to this example. In an implementation, the first and second data storing layers DL1 and DL2 may include at least one of charge-trapping materials. As an example, the first and second data storing layers DL1 and DL2 may be formed of or include at least one of nitride materials (e.g., SiN), but is not limited to this example. In an implementation, each of the first and second data storing layers DL1 and DL2 may include a ferroelectric material, a floating gate electrode, or conductive nanodots. The first and second blocking layers BO1 and BO2 may include at least one of oxide materials (e.g., SiO, AlO, or HfO), but are not limited to this example.

Each of the first memory channel structures CS may further include a first bit line pad 185. Each of the second memory channel structures TS may further include a second bit line pad 195. Each of the first and second bit line pads 185 and 195 may be electrically connected to the peripheral transistor 101 through the bit line contact 138, the bit line 136, the connection contact 134, the second bonding pad 132, the first bonding pad 122, the peripheral conductive line 106, and the peripheral contact 105. The first and second bit line pads 185 and 195 may include a conductive material. As an example, the first and second bit line pads 185 and 195 may include poly silicon or metallic materials, but are not limited to this example.

The division structures DS may be extended in the third direction D3 to penetrate the first to third gate stacks GST1, GST2, and GST3. The division structures DS may be extended in the first direction D1. The division structure DS may include an insulating material. In an implementation, the division structure DS may include a conductive material enclosed by the insulating material.

The supporting structures SUS may be provided to penetrate the first gate stack GST1, the second gate stack GST2, and the third gate stack GST3. The supporting structure SUS may have a similar structure to the first memory channel structure CS. In an implementation, the supporting structure SUS may be formed of only an insulating material, unlike the first memory channel structure CS.

Each of the penetration contacts TC may be connected to the conductive patterns CP of the first to third gate stacks GST1, GST2, and GST3. The penetration contact TC may include a conductive material.

The source structure SST may be provided on the third gate stack GST3, the first memory layer 183, the second memory layer 193, the first channel layer 187, and the second channel layer 197. The source structure SST may include a first source layer SL1 on the third gate stack GST3, the first memory layer 183, the second memory layer 193, the first channel layer 187, and the second channel layer 197, a second source layer SL2 on the first source layer SL1, and a third source layer SL3 on the second source layer SL2. The first source layer SL1 may be provided on the first cell region IR and the second cell region OR. The second source layer SL2 and the third source layer SL3 may be provided on the first cell region IR.

The first source layer SL1 may be in contact with the first memory channel structure CS, the second memory channel structure TS, and the division structure DS. A side surface of the first source layer SL1 may be in contact with the first memory layer 183 and the second memory layer 193. The second source layer SL2 may be in contact with the first memory channel structure CS and the division structure DS. The second source layer SL2 may be spaced apart from the second memory channel structure TS. The third source layer SL3 may be spaced apart from the first memory channel structure CS and the division structure DS.

The first, second, and third source layers SL1, SL2, and SL3 may include a conductive material. As an example, the first and third source layers SL1 and SL3 may be formed of or include doped poly silicon, and the second source layer SL2 may be formed of or include undoped poly silicon. The first source layer SL1 may contain impurities of a first conductivity type. The second source layer SL2 may be formed of or include an impurity-free material. The third source layer SL3 may contain impurities of a second conductivity type. In an implementation, the first conductivity type may be an n-type, and the second conductivity type may be a p-type. The semiconductor device may be configured to perform a bulk erase operation. The first, second, and third source layers SL1, SL2, and SL3 of the source structure SST may be electrically connected to the first and second channel layers 187 and 197.

In an implementation, the second source layer SL2 may include doped silicon. In this case, the second source layer SL2 may contain impurities of the same conductivity type (e.g., the first conductivity type) as the first source layer SL1. For example, the first source layer SL1 may contain impurities of the first conductivity type at a first concentration, and the second source layer SL2 may contain impurities of the first conductivity type at a second concentration. Here, the first concentration of the first source layer SL1 may be higher than the second concentration of the second source layer SL2.

In an implementation, the second source layer SL2 may be formed through a selective epitaxial growth (SEG) process. As an example, the second source layer SL2 may be formed of or include single-crystalline silicon.

The first barrier layer BM1 may be provided on the first cell region IR. The first barrier layer BM1 may be conformally provided on the third source layer SL3. The second barrier layer BM2 may be provided on the second cell region OR. The second barrier layer BM2 may be conformally provided on a top surface of the second memory layer 193, the second channel layer 197, and a portion of the first source layer SL1. The first and second barrier layers BM1 and BM2 may include a conductive material. As an example, the first and second barrier layers BM1 and BM2 may be formed of or include tungsten (W).

The first source layer SL1 may include an exposed surface SL1_a, on the second cell region OR. The second barrier layer BM2 and the second source layer SL2 may cover a portion of a top surface of the first source layer SL1, and here, the exposed surface SL1_a may be another portion of the top surface of the first source layer SL1 that is not covered with the second barrier layer BM2 and the second source layer SL2. The exposed surface SL1_a of the first source layer SL1 may be placed between the first barrier layer BM1 and the second barrier layer BM2.

The via structures BV may be provided on the first and second barrier layers BM1 and BM2. The via structures BV may be in contact with the first and second barrier layers BM1 and BM2. The via structure BV may include a conductive material.

The cover insulating layer 150 may be provided on the exposed surface SL1_a of the first source layer SL1, the first barrier layer BM1, and the second barrier layer BM2. The cover insulating layer 150 may enclose the via structure BV. The cover insulating layer 150 may include an insulating material.

A top surface 183_U of the first memory layer 183 of the first memory channel structure CS may be in contact with the second source layer SL2. The top surface 183_U of the first memory layer 183 may include a top surface TL1_U of the first tunnel insulating layer TL1, a top surface DL1_U of the first data storing layer DL1, and a top surface BO1_U of the first blocking layer BO1. A level of each of the top surfaces TL1_U, DL1_U, and BO1_U of the first tunnel insulating layer TL1, the first data storing layer DL1, and the first blocking layer BO1 may be higher than a level of a bottom surface of the first source layer SL1. A level of each of the top surfaces TL1_U, DL1_U, and BO1_U of the first tunnel insulating layer TL1, the first data storing layer DL1, and the first blocking layer BO1 may be lower than a level of the top surface of the first source layer SL1. The top surface TL1_U of the first tunnel insulating layer TL1, the top surface DL1_U of the first data storing layer DL1, and the top surface BO1_U of the first blocking layer BO1 may be coplanar with each other. In an implementation, the top surface TL1_U of the first tunnel insulating layer TL1, the top surface DL1_U of the first data storing layer DL1, and the top surface BO1_U of the first blocking layer BO1 may be placed at different levels from each other.

A top surface of the second memory layer 193 of the second memory channel structure TS may be in contact with the second barrier layer BM2. The top surface of the second memory layer 193 may include a top surface of the second tunnel insulating layer TL2, a top surface of the second data storing layer DL2, and a top surface of the second blocking layer BO2. A level of each of the top surfaces of the second tunnel insulating layer TL2, the second data storing layer DL2, and the second blocking layer BO2 may be higher than a level of a top surface of the upper insulating pattern UIP. The level of each of the top surfaces of the second tunnel insulating layer TL2, the second data storing layer DL2, and the second blocking layer BO2 may be higher than the level of the bottom surface of the first source layer SL1. The level of each of the top surfaces of the second tunnel insulating layer TL2, the second data storing layer DL2, and the second blocking layer BO2 may be lower than the level of the top surface of the first source layer SL1. The top surface of the second tunnel insulating layer TL2, the top surface of the second data storing layer DL2, and the top surface of the second blocking layer BO2 may be coplanar with each other. In an implementation, the top surface of the second tunnel insulating layer TL2, the top surface of the second data storing layer DL2, and the top surface of the second blocking layer BO2 may be located at different levels.

The second source layer SL2 may include an intervening portion SL2_IN, which is interposed between the first channel layer 187 of the first memory channel structure CS and the first source layer SL1. The intervening portion SL2_IN of the second source layer SL2 may be in contact with a side surface of the first channel layer 187, the top surface 183_U of the first memory layer 183, and a portion of the side surface of the first source layer SL1. A remaining portion of the side surface of the first source layer SL1 may be in contact with a side surface of the first blocking layer BO1. A thickness of the intervening portion SL2_IN of the second source layer SL2 in the third direction D3 may be smaller than a thickness of the first source layer SL1 in the third direction D3. A level of a bottom surface of the intervening portion SL2_IN of the second source layer SL2 may be higher than the level of the bottom surface of the first source layer SL1. The level of the bottom surface of the intervening portion SL2_IN of the second source layer SL2 may be lower than a level of the top surface of the first source layer SL1.

The second source layer SL2 may include a first top surface SL2_U1, a second top surface SL2_U2, and a side surface SL2_S. The second top surface SL2_U2 of the second source layer SL2 may be disposed at a level higher than a first top surface SL2_U1. The second top surface SL2_U2 of the second source layer SL2 may be overlapped with the first memory channel structure CS. The side surface SL2_S of the second source layer SL2 may connect the first top surface SL2_U1 to the second top surface SL2_U2. The side surface SL2_S of the second source layer SL2 may have a curved shape. As an example, the side surface SL2_S of the second source layer SL2 may be convex toward the first barrier layer BM1.

The third source layer SL3 may include a first top surface SL3_U1, a second top surface SL3_U2, and a side surface SL3_S. The first top surface SL3_U1 of the third source layer SL3 may be disposed on the first top surface SL2_U1 of the second source layer SL2. The second top surface SL3_U2 of the third source layer SL3 may be disposed on a level higher than the first top surface SL3_U1. The second top surface SL3_U2 of the third source layer SL3 may be disposed on the second top surface SL2_U2 of the second source layer SL2. The second top surface SL3_U2 of the third source layer SL3 may be overlapped with the first memory channel structure CS. The side surface SL3_S of the third source layer SL3 may connect the first top surface SL3_U1 to the second top surface SL3_U2. The side surface SL3_S of the third source layer SL3 may be disposed on the side surface SL2_S of the second source layer SL2. The side surface SL3_S of the third source layer SL3 may have a curved shape. As an example, the side surface SL3_S of the third source layer SL3 may be convex toward the first barrier layer BM1.

In an example semiconductor device, since the impurity-free second source layer SL2 is provided between the first and third source layer SL1 and SL3, it may be possible to prevent impurities in the first or third source layer SL1 or SL3 from being excessively diffused and to improve the reliability characteristics of the semiconductor device.

In an example semiconductor device, the second source layer SL2 includes the intervening portion SL2_IN, which is at a lower level that an upper surface of the first channel layer 187. This increases an overlapping region where the impurities of the first source layer SL1 are diffused, and thus improves the electrical characteristics of the semiconductor device.

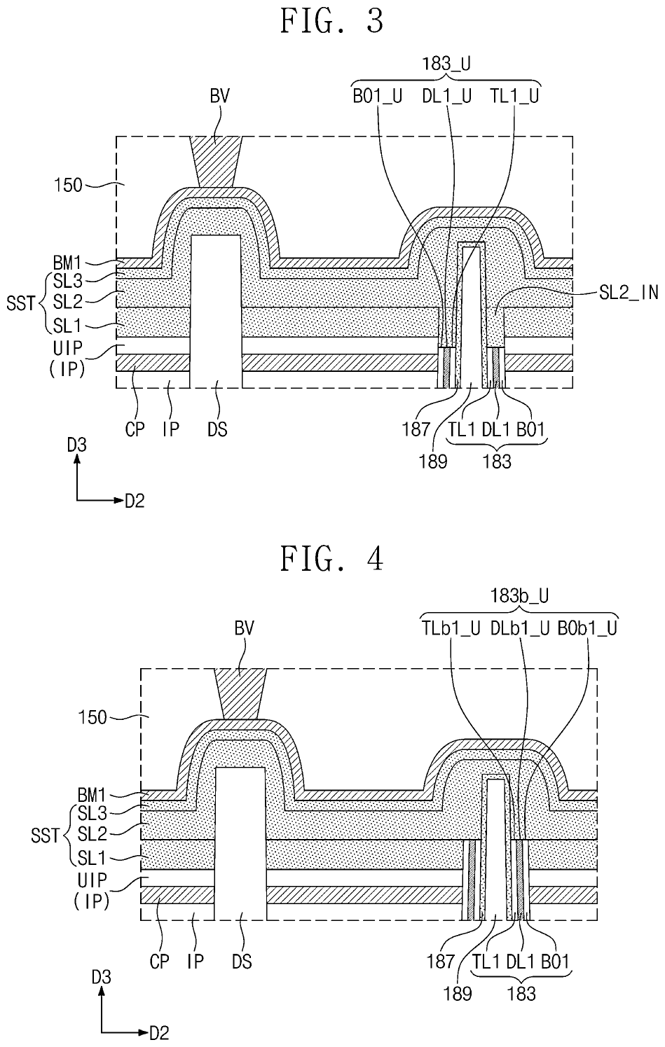

FIG. 3 is an enlarged sectional view illustrating an example semiconductor device. The semiconductor device of FIG. 3 may have similar features to the semiconductor device of FIG. 2A to 2C, except for the features to be described below.

Referring to FIG. 3, a level of the top surface 183_U of the first memory layer 183 of the first memory channel structure CS may be lower than the level of the bottom surface of the first source layer SL1. The level of the top surface 183_U of the first memory layer 183 of the first memory channel structure CS may be higher than a level of a bottom surface of the upper insulating pattern UIP.

The intervening portion SL2_IN of the second source layer SL2 may be in contact with the side surface of the first channel layer 187, the top surface 183_U of the first memory layer 183, the side surface of the first source layer SL1, and a portion of a side surface of the upper insulating pattern UIP. A remaining portion of the side surface of the upper insulating pattern UIP may be in contact with a side surface of the first blocking layer BO1.

A thickness of the intervening portion SL2_IN of the second source layer SL2 in the third direction D3 may be larger than a thickness of the first source layer SL1 in the third direction D3. The level of the bottom surface of the intervening portion SL2_IN of the second source layer SL2 may be lower than the level of the bottom surface of the first source layer SL1. The level of the bottom surface of the intervening portion SL2_IN of the second source layer SL2 may be higher than a level of the bottom surface of the upper insulating pattern UIP.

FIG. 4 is an enlarged sectional view illustrating an example semiconductor device. The semiconductor device of FIG. 4 may have similar features to the semiconductor device of FIG. 2A to 2C, except for the features to be described below.

Referring to FIG. 4, the second source layer SL2 may not include the intervening portion. The side surface of the first source layer SL1 may be in contact with the side surface of the first blocking layer BO1. The top surface 183b_U of the first memory layer 183 of the first memory channel structure CS may be placed at the same level as the top surface of the first source layer SL1. The top surface of the first source layer SL1, the top surface TL1b_U of the first tunnel insulating layer TL1, the top surface DL1b_U of the first data storing layer DL1, and the top surface BO1b_U of the first blocking layer BO1 may be coplanar with each other.

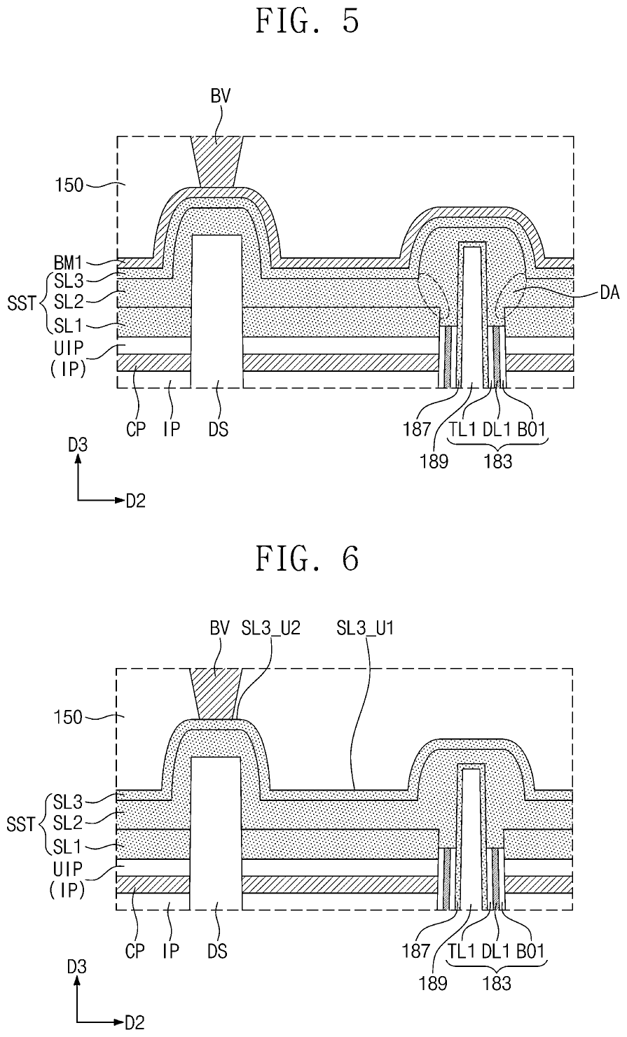

FIG. 5 is an enlarged sectional view illustrating an example semiconductor device. The semiconductor device of FIG. 5 may have similar features to the semiconductor device of FIG. 2A to 2C, except for the features to be described below.

Referring to FIG. 5, the source structure SST may further include a doped region DA. The doped region DA may include a portion of the first source layer SL1 and a portion of the second source layer SL2. The first channel layer 187 of the first memory channel structure CS may be enclosed by the doped region DA.

The doped region DA may be formed by doping the portion of the first source layer SL1 and the portion of the second source layer SL2 with impurities. The first source layer SL1 may contain impurities of the first conductivity type. The second source layer SL2 may be formed of or include an impurity-free material. The third source layer SL3 may contain impurities of the second conductivity type at a third concentration. The doped region DA may contain impurities of the second conductivity type at a fourth concentration. The third concentration of the third source layer SL3 may be higher than the fourth concentration of the doped region DA. In an implementation, the first conductivity type may be an n-type, and the second conductivity type may be a p-type.

FIG. 6 is an enlarged sectional view illustrating an example semiconductor device. The semiconductor device of FIG. 6 may have similar features to the semiconductor device of FIG. 2A to 2C, except for the features to be described below.

Referring to FIG. 6, the semiconductor device may not include a barrier layer. The third source layer SL3 may be in contact with the via structure BV. The cover insulating layer 150 may cover the third source layer SL3. The second top surface of the third source layer SL3 may be in contact with the cover insulating layer 150.

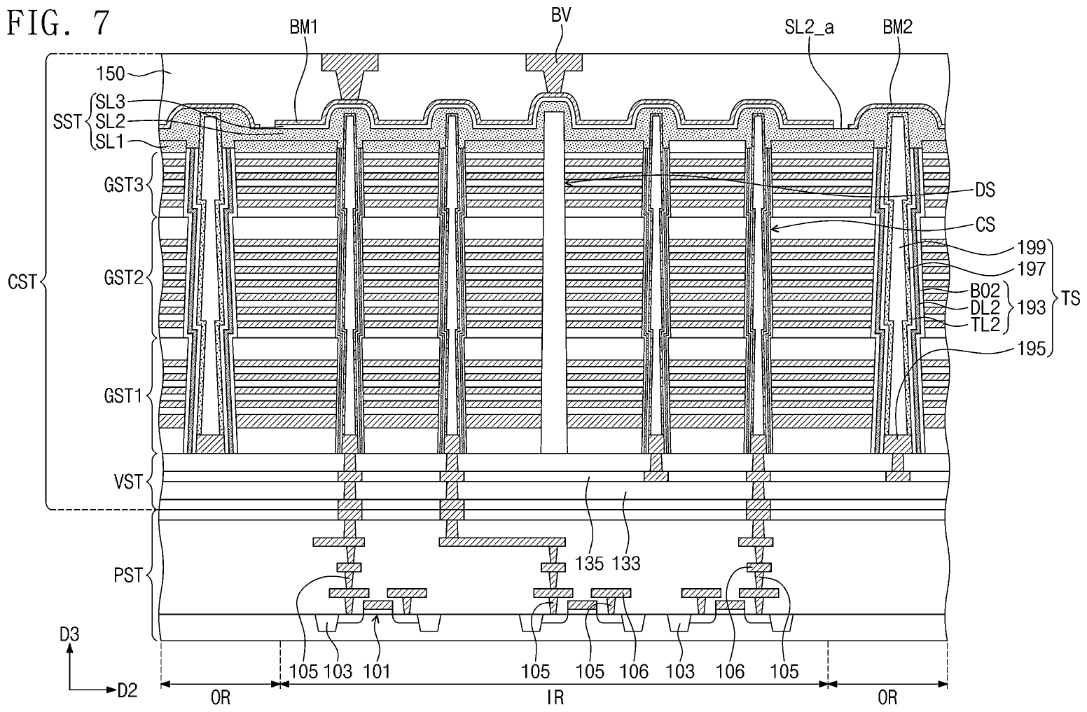

FIG. 7 is a sectional view illustrating an example semiconductor device. The semiconductor device of FIG. 7 may have similar features to the semiconductor device of FIG. 2A to 2C, except for the features to be described below.

Referring to FIG. 7, the second source layer SL2 may be provided on the first cell region IR and the second cell region OR. The second source layer SL2 may be in contact with a top surface of the second memory layer 193 and a portion of the second channel layer 197. The third source layer SL3 may be spaced apart from the second memory channel structure TS.

The first barrier layer BM1 may be provided on the first cell region IR. The second barrier layer BM2 may be provided on the second cell region OR. The first barrier layer BM1 may be conformally provided on the third source layer SL3. The second barrier layer BM2 may be conformally provided on the second source layer SL2. The first barrier layer BM1 may be in contact with the third source layer SL3. The second barrier layer BM2 may be in contact with the second source layer SL2.

The second source layer SL2 may include an exposed surface SL2_a, on the second cell region OR. The second barrier layer BM2 and the third source layer SL3 may cover a portion of a top surface of the second source layer SL2, and here, the exposed surface SL2_a may be another portion of the top surface of the second source layer SL2 that is not covered with the second barrier layer BM2 and the third source layer SL3. The exposed surface SL2_a of the second source layer SL2 may be placed between the first barrier layer BM1 and the second barrier layer BM2. The exposed surface SL2_a of the second source layer SL2 may be in contact with the cover insulating layer 150.

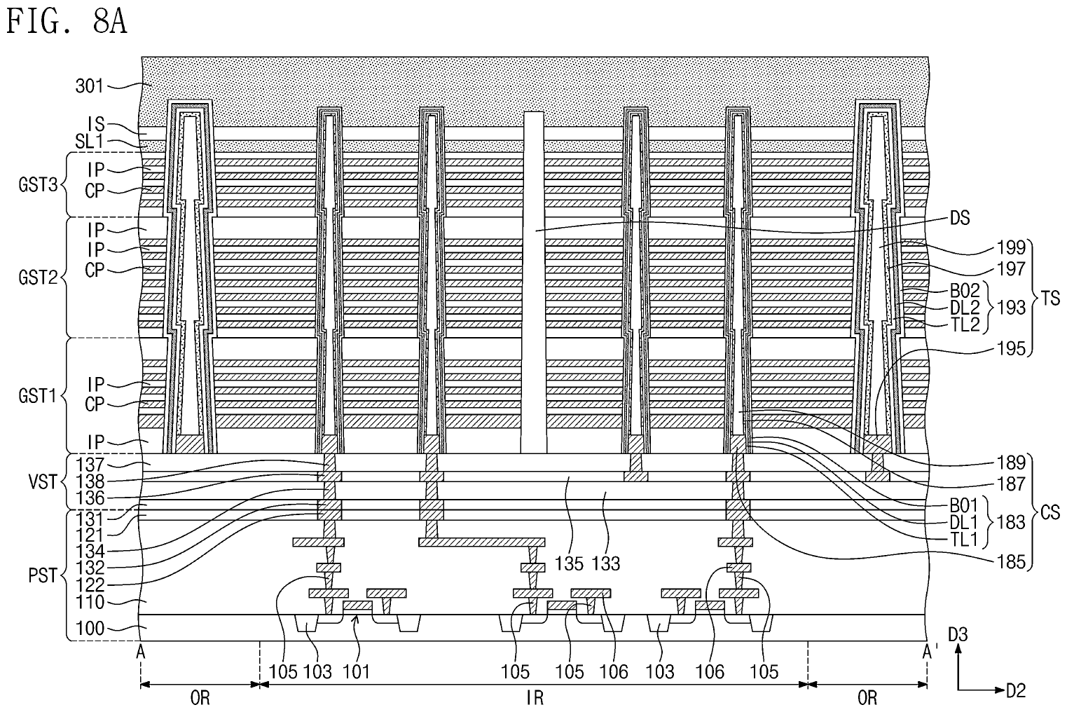

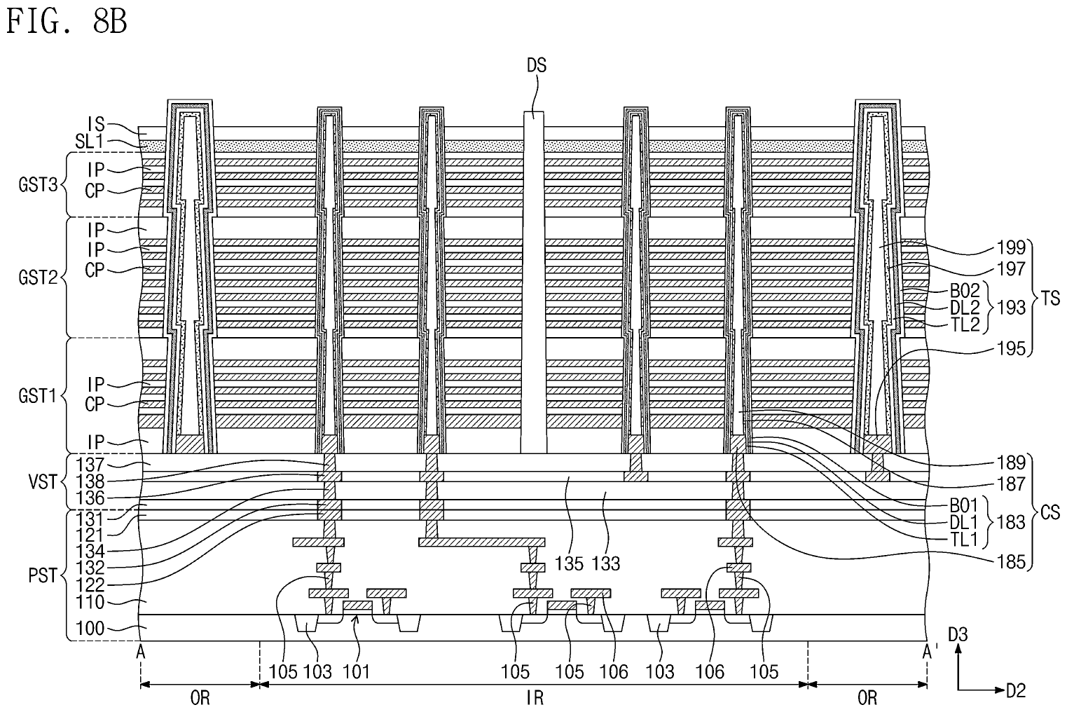

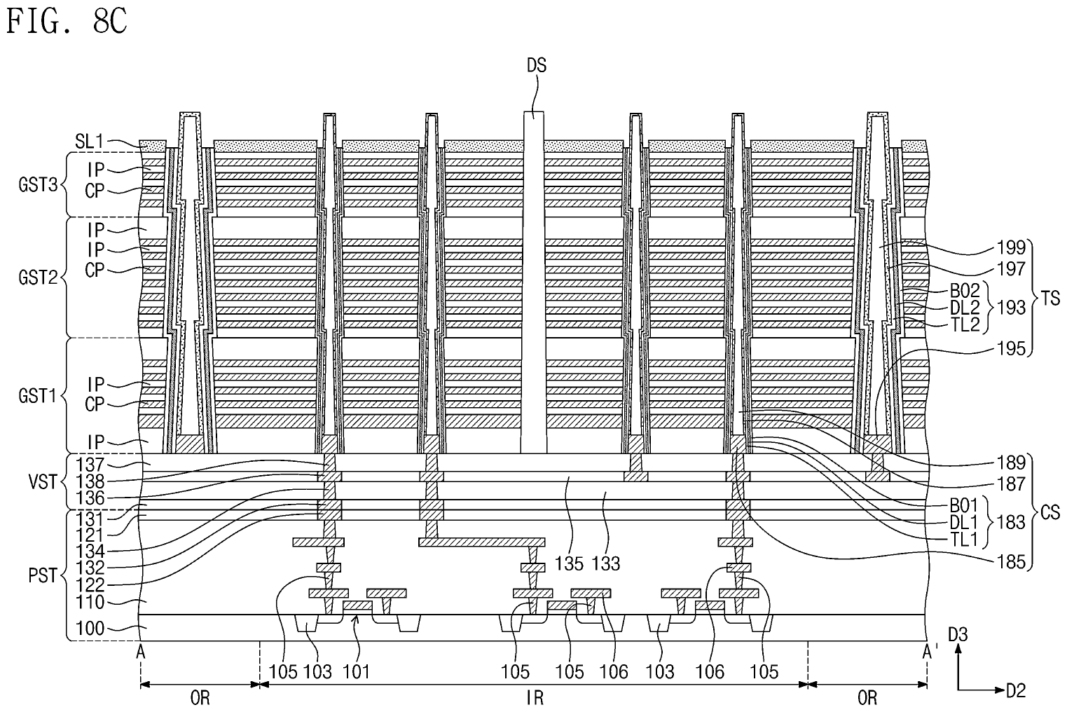

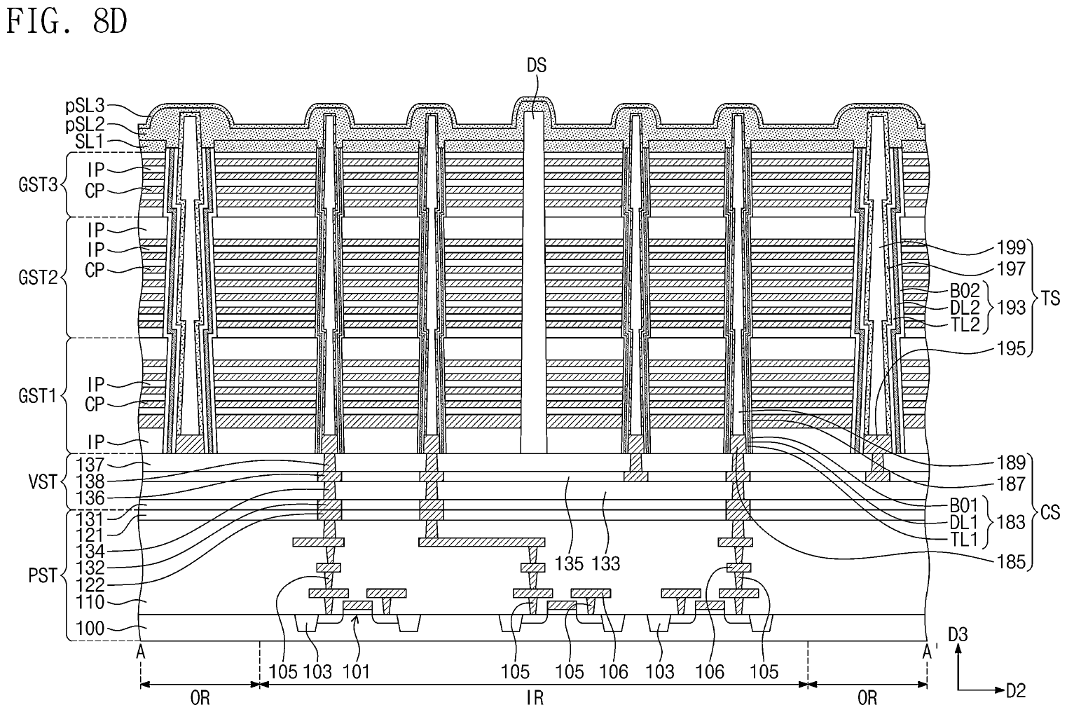

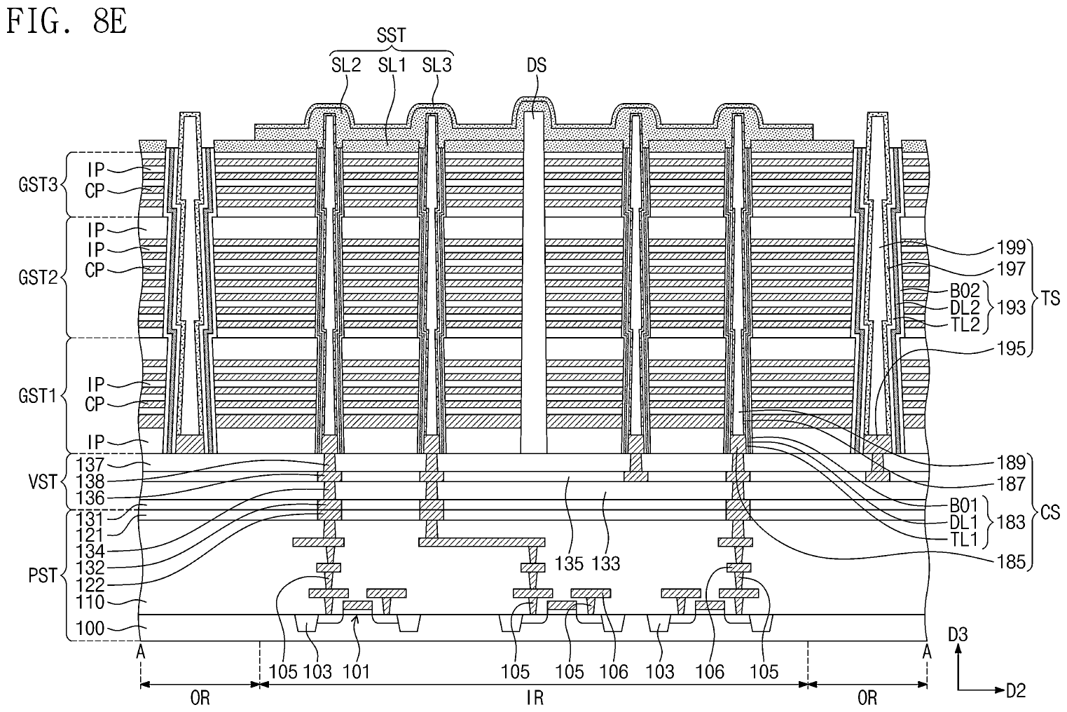

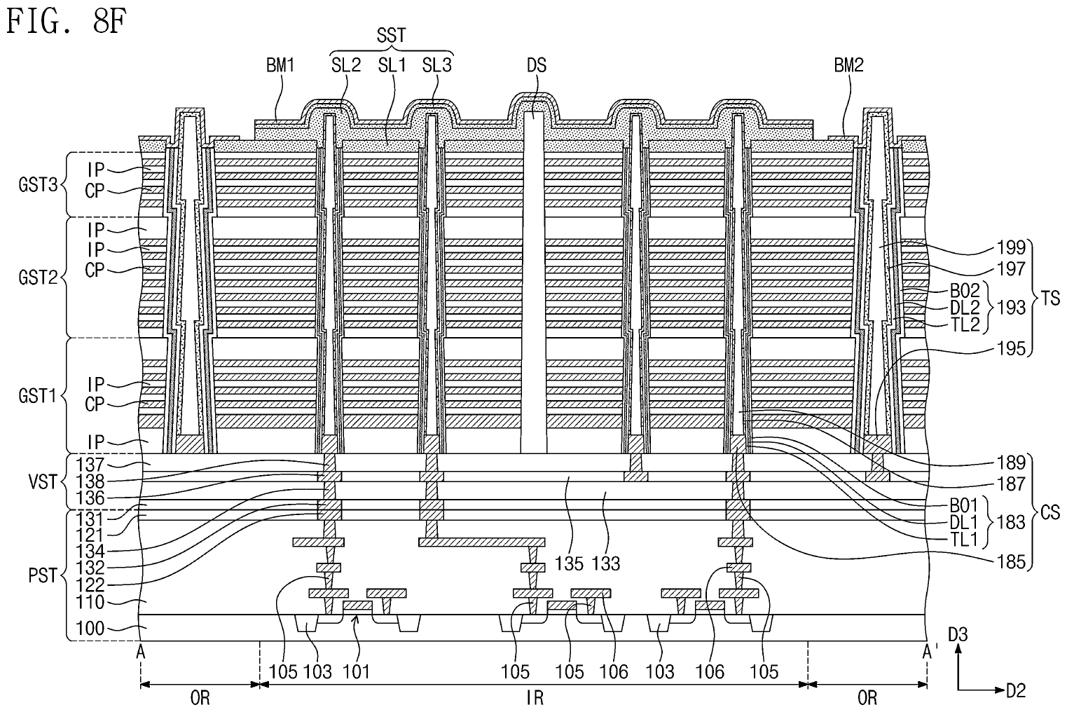

FIGS. 8A, 8B, 8C, 8D, 8E, and 8F are sectional views illustrating an example method of fabricating a semiconductor device. FIGS. 8A, 8B, 8C, 8D, 8E, and 8F illustrate a portion of the semiconductor device corresponding to FIG. 2B.

Referring to FIG. 8A, a sacrificial substrate 301 may be formed. The sacrificial substrate 301 may be provided on a sacrificial layer IS, the first memory channel structure CS, the second memory channel structure TS, and the division structure DS. In an implementation, the sacrificial substrate 301 may be a semiconductor substrate, an insulating substrate, a silicon-on-insulator (SOI) substrate, or a germanium-on-insulator (GOI) substrate.

The sacrificial layer IS may be formed. The first source layer SL1 may be formed. The sacrificial layer IS may be provided on the first source layer SL1. The first source layer SL1 may be provided on the third gate stack GST3. The sacrificial layer IS may include an insulating material.

The peripheral circuit structure PST, the lower interconnection structure VST, the first gate stack GST1, the second gate stack GST2, and the third gate stack GST3 may be formed.

The first memory channel structures CS, the second memory channel structures TS, and the division structure DS may be formed to penetrate the first to third gate stacks GST1, GST2, and GST3. The formation of the first memory channel structure CS may include forming the first blocking layer BO1, the first data storing layer DL1, the first tunnel insulating layer TL1, the first channel layer 187, the first insulating capping layer 189, and the first bit line pad 185. The formation of the second memory channel structure TS may include forming the second blocking layer BO2, the second data storing layer DL2, the second tunnel insulating layer TL2, the second channel layer 197, the second insulating capping layer 199, and the second bit line pad 195.

Referring to FIG. 8B, the sacrificial substrate 301 may be removed. In an implementation, the sacrificial substrate 301 may be removed to expose an upper portion of the first memory channel structure CS, an upper portion of the second memory channel structure TS, an upper portion of the division structure DS, and a top surface of the sacrificial layer IS. In an implementation, the sacrificial substrate 301 may be removed through a grinding process.

Referring to FIG. 8C, the sacrificial layer IS may be removed. In an implementation, the sacrificial layer IS may be removed by a wet etching process. As a result of the removal of the sacrificial layer IS, the top surface of the first source layer SL1 may be exposed to the outside.

The first memory layer 183 and the second memory layer 193 may be etched, after the removal of the sacrificial layer IS. As a result of the etching of the first memory layer 183 and the second memory layer 193, a portion of the side surface of the first source layer SL1 may be exposed. The etching of the first memory layer 183 may include etching the first blocking layer BO1, etching the first data storing layer DL1, and etching the first tunnel insulating layer TL1.

Referring to FIG. 8D, a first preliminary source layer pSL2 may be formed. The first preliminary source layer pSL2 may be provided on the first cell region IR and the second cell region OR. The first preliminary source layer pSL2 may be formed on the first source layer SL1, the first tunnel insulating layer TL1, the first data storing layer DL1, the first blocking layer BO1, and the first channel layer 187. The first preliminary source layer pSL2 may be in contact with the top surface of the first source layer SL1, the side surface of the first source layer SL1, the top surface of the first tunnel insulating layer TL1, the top surface of the first data storing layer DL1, and the top surface of the first blocking layer BO1.

A second preliminary source layer pSL3 may be formed. The second preliminary source layer pSL3 may be provided on the first cell region IR and the second cell region OR. The second preliminary source layer pSL3 may be conformally formed on the first preliminary source layer pSL2.

In an implementation, the second preliminary source layer pSL3 may be in an inactivated state. The second preliminary source layer pSL3 in the inactivated state may be activated through a melting laser annealing (MLA) process.

Referring to FIG. 8E, portions of the first and second preliminary source layers pSL2 and pSL3 on the second cell region OR may be removed. The second source layer SL2 and the third source layer SL3 may be formed as a result of the partial removal of the first and second preliminary source layers pSL2 and pSL3. The second source layer SL2 and the third source layer SL3 may constitute the source structure SST. As a result of the partial removal of the first and second preliminary source layers pSL2 and pSL3, a top surface of the first source layer SL1, a top surface of the second memory layer 193, and an upper portion of the second channel layer 197 on the second cell region OR may be exposed to the outside. In an implementation, the portion of the first preliminary source layer pSL2 and the portion of the second preliminary source layer pSL3 may be removed by an etch-back process.

Referring to FIG. 8F, the first barrier layer BM1 and the second barrier layer BM2 may be formed. The formation of the first barrier layer BM1 and the second barrier layer BM2 may include conformally forming a barrier layer (not shown) on the source structure SST and the second memory channel structure TS and removing a portion of the barrier layer (not shown) on the second cell region OR. As a result of the partial removal of the barrier layer (not shown), a portion of the top surface of the first source layer SL1 on the second cell region OR may be exposed to the outside.

Referring to FIG. 2B, the cover insulating layer 150 may be formed on the first barrier layer BM1, the second barrier layer BM2, and the first source layer SL1. The via structures BV may be formed to penetrate the cover insulating layer 150 and may be connected to the first barrier layer BM1 and the second barrier layer BM2.

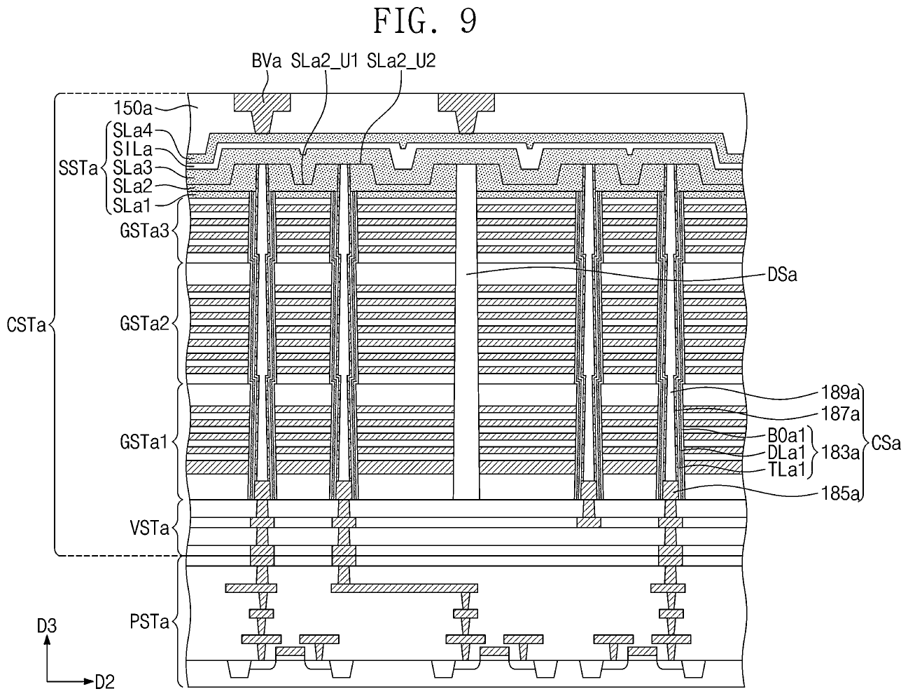

FIG. 9 is a sectional view illustrating an example semiconductor device.

Referring to FIG. 9, the semiconductor device may include a peripheral circuit structure PSTa and a memory cell structure CSTa. The memory cell structure CSTa may include a lower interconnection structure VSTa, a first gate stack GSTa1, a second gate stack GSTa2, a third gate stack GSTa3, first memory channel structures CSa, a division structure Dsa, a source structure SSTa, via structures Bva, and a cover insulating layer 150a.

The first memory channel structure Csa may include a first insulating capping layer 189a, a first channel layer 187a, and a first memory layer 183a. The source structure SSTa may include a first source layer Sla1, a second source layer Sla2, a third source layer Sla3, a fourth source layer Sla4, and a source insulating layer SILa.

The second source layer Sla2 may be disposed on the first source layer Sla1. The third source layer Sla3 may be disposed on the second source layer Sla2. The source insulating layer SILa may be disposed on the third source layer Sla3. The fourth source layer Sla4 may be disposed on the source insulating layer SILa.

The first to fourth source layers Sla1, Sla2, Sla3, and Sla4 may include a conductive material. As an example, the first and second source layers Sla1 and Sla2 may be formed of or include undoped poly silicon, and the third and fourth source layers Sla3 and Sla4 may be formed of or include doped poly silicon. The first and second source layers Sla1 and Sla2 may be formed of or include an impurity-free material. The third source layer Sla3 may contain impurities of a first conductivity type. The fourth source layer Sla4 may contain impurities of a second conductivity type. In an implementation, the first conductivity type may be an n-type, and the second conductivity type may be a p-type.

The source insulating layer SILa may include an insulating material. As an example, the source insulating layer SILa may be formed of or include an oxide material.

The first memory layer 183a of the first memory channel structure Csa may be in contact with the second source layer Sla2. The first memory layer 183a of the first memory channel structure Csa may be coplanar with a top surface of the first source layer Sla1.

Top surfaces of the first channel and insulating capping layers 187a and 189a of the first memory channel structure Csa may be exposed. The top surfaces of the first channel and insulating capping layers 187a and 189a of the first memory channel structure Csa may be in contact with the third source layer Sla3. The second source layer Sla2 may include a first top surface Sla2_U1 and a second top surface Sla2_U2, which is located at a level higher than the first top surface Sla2_U1. The top surfaces of the first channel and insulating capping layers 187a and 189a of the first memory channel structure Csa may be coplanar with the second top surface Sla2_U2 of the second source layer Sla2.

The cover insulating layer 150a may cover a top surface of the fourth source layer Sla4. The cover insulating layer 150a may be in contact with the top surface of the fourth source layer Sla4. The via structure Bva may penetrate the cover insulating layer 150a and may be in contact with the top surface of the fourth source layer Sla4.

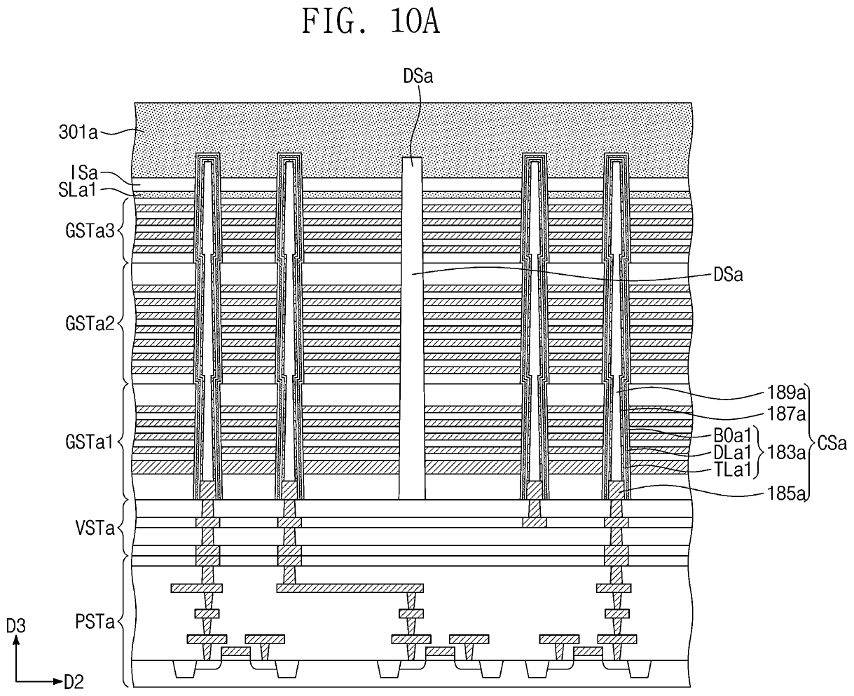

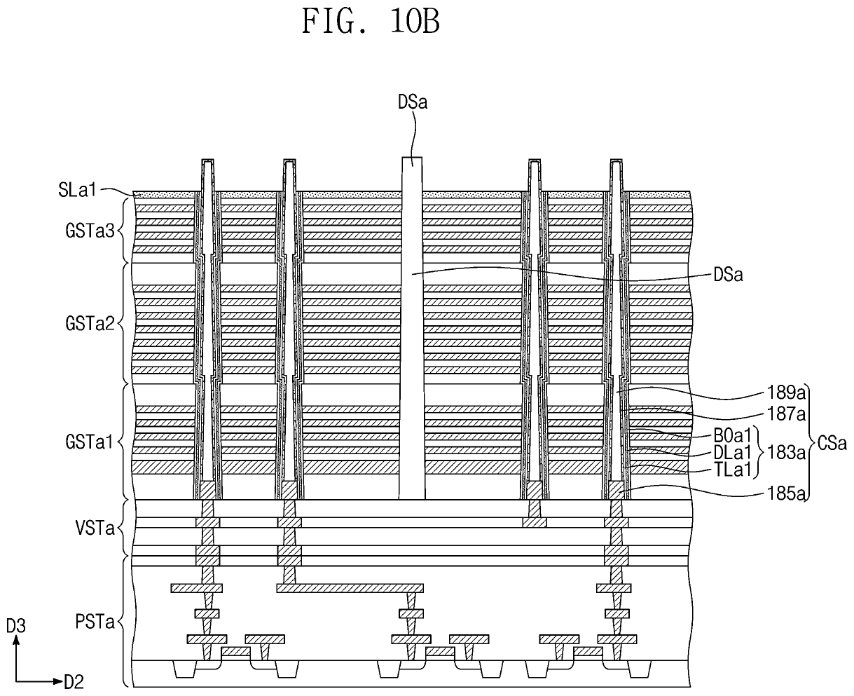

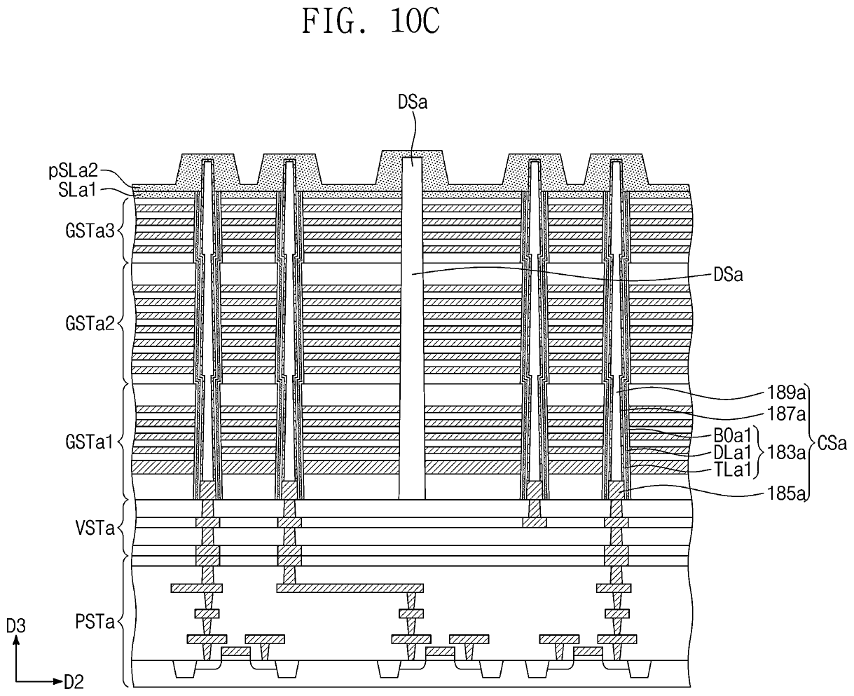

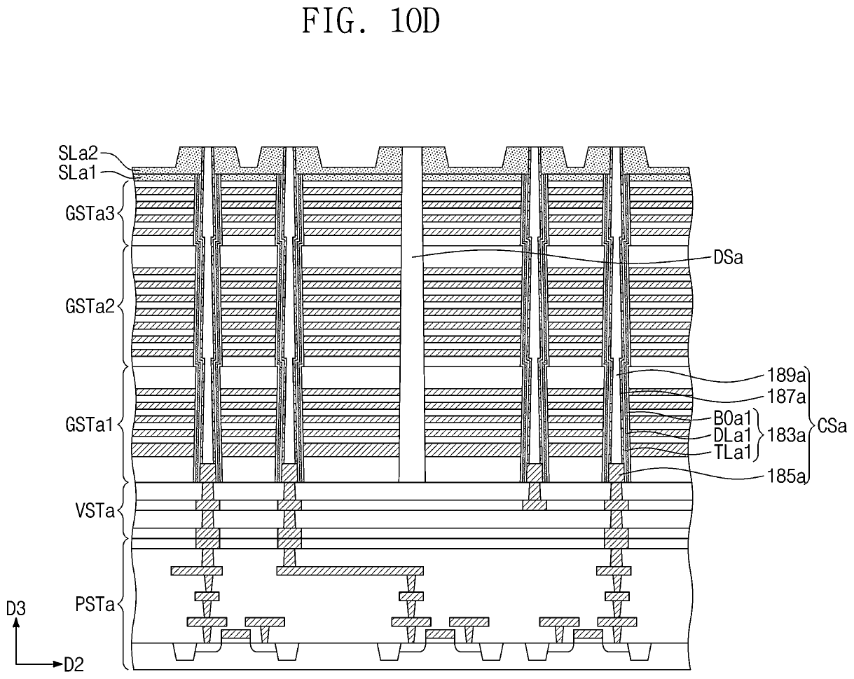

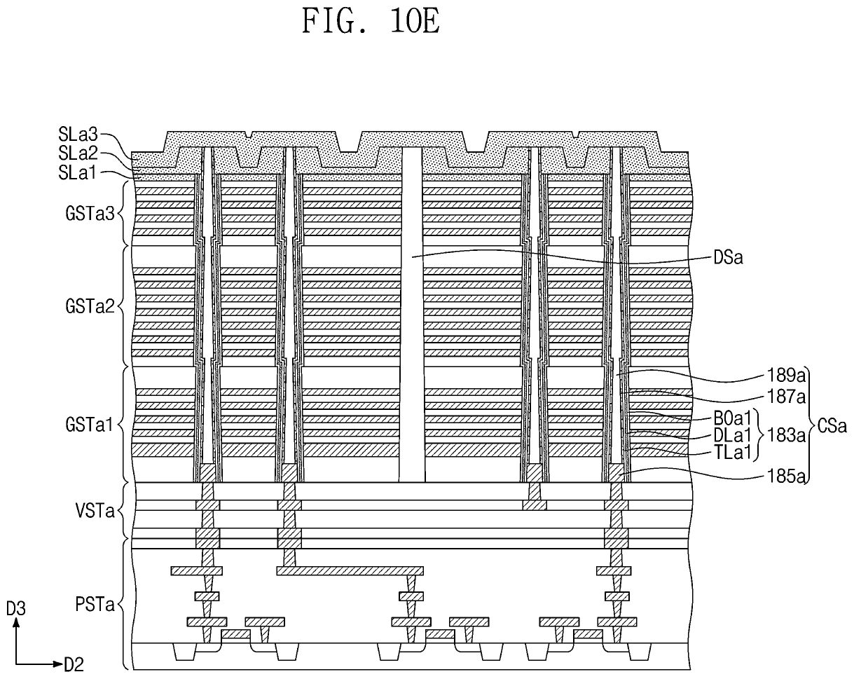

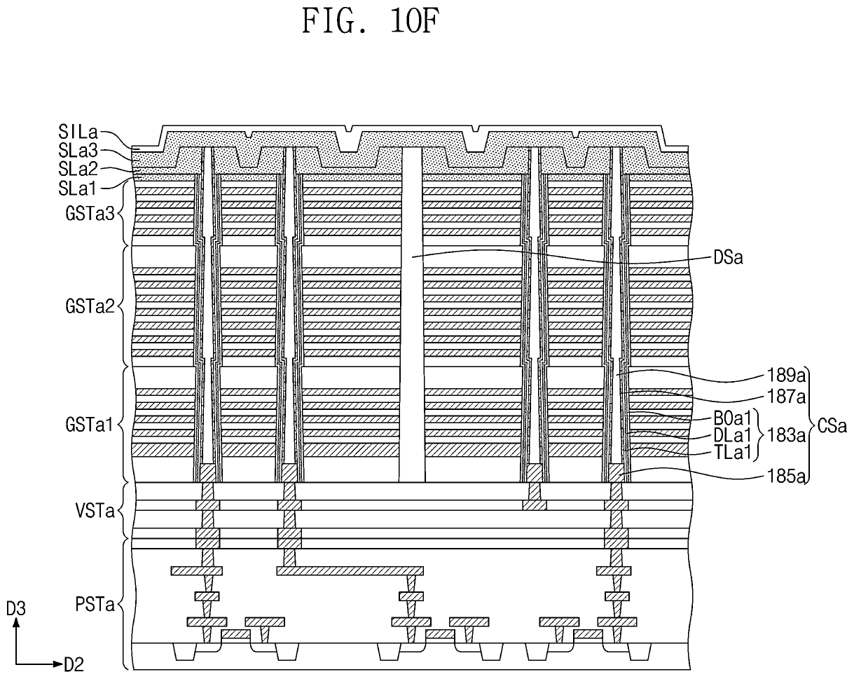

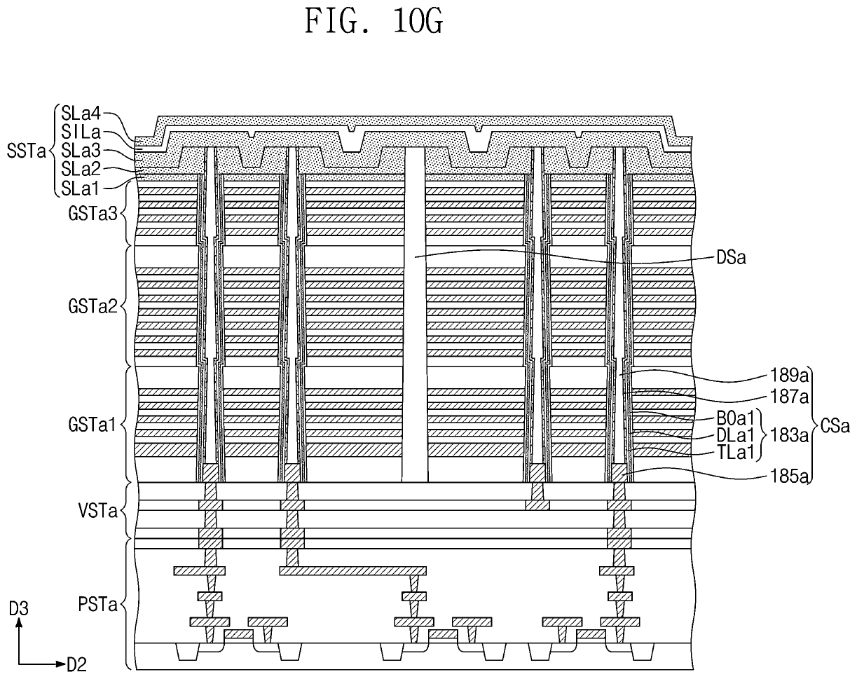

FIGS. 10A, 10B, 10C, 10D, 10E, 10F, and 10G are sectional views illustrating an example method of fabricating a semiconductor device. FIGS. 10A, 10B, 10C, 10D, 10E, 10F, and 10G illustrate a portion of the semiconductor device corresponding to FIG. 9.

Referring to FIG. 10A, the peripheral circuit structure PSTa, the lower interconnection structure VSTa, the first gate stack GSTa1, the second gate stack GSTa2, and the third gate stack GSTa3 may be formed.

The first memory channel structures CSa and the division structure DSa may be formed to penetrate the first to third gate stacks GSTa1, GSTa2, and GSTa3. The formation of the first memory channel structure CSa may include forming a first blocking layer BOa1, a first data storing layer DLa1, a first tunnel insulating layer TLa1, a first channel layer 187a, a first insulating capping layer 189a, and a first bit line pad 185a.

The first source layer SLa1 may be formed. The first source layer SLa1 may be provided on the third gate stack GSTa3.

A sacrificial layer ISa may be formed. The sacrificial layer ISa may be provided on the first source layer SLa1. The sacrificial layer ISa may include an insulating material.

A sacrificial substrate 301a may be formed. The sacrificial substrate 301a may be provided on the sacrificial layer ISa, the first memory channel structure CSa, and the division structure DSa. In an implementation, the sacrificial substrate 301a may be a semiconductor substrate, an insulating substrate, a silicon-on-insulator (SOI) substrate, or a germanium-on-insulator (GOI) substrate.

Referring to FIG. 10B, the sacrificial substrate 301a and the sacrificial layer ISa may be removed. A top surface of the first memory layer 183a, an upper portion of the first channel layer 187a, an upper portion of the division structure DSa, and a top surface of the first source layer SLa1 may be exposed as a result of the removal of the sacrificial substrate 301a and the sacrificial layer ISa. In an implementation, the sacrificial substrate 301 may be removed by a grinding process. In an implementation, the sacrificial layer ISa may be removed by a wet etching process.

Referring to FIG. 10C, a first preliminary source layer pSLa2 may be formed. The first preliminary source layer pSLa2 may be formed on the top surface of the first memory layer 183a, the upper portion of the first channel layer 187a, an upper portion of the division structure described above, and the top surface of the first source layer SL1. The first preliminary source layer pSLa2 may be in contact with the top surface of the first memory layer 183a, the first channel layer 187a, the division structure DSa, and the top surface of the first source layer SLa1.

Referring to FIG. 10D, a portion of the first preliminary source layer pSLa2, an upper portion of the first channel layer 187a, an upper portion of the first insulating capping layer 189a, and an upper portion of the division structure DSa may be removed. Since the portion of the first preliminary source layer pSLa2, the upper portion of the first channel layer 187a, the upper portion of the first insulating capping layer 189a, and the upper portion of the division structure DSa are removed, the top surface of the first channel layer 187a, the top surface of the first insulating capping layer 189a, and a top surface of the division structure DSa may be exposed to the outside. The first preliminary source layer pSLa2, which is left after the partial removal, may be defined as the second source layer SLa2. In an implementation, the portion of the first preliminary source layer pSLa2, the upper portion of the first channel layer 187a, the upper portion of the first insulating capping layer 189a, and the upper portion of the division structure DSa may be removed by a chemical-mechanical polishing process.

Referring to FIG. 10E, the third source layer SLa3 may be formed. The third source layer SLa3 may be formed on the second source layer SLa2.

Referring to FIG. 10F, the source insulating layer SILa may be formed. The source insulating layer SILa may be formed on the third source layer SLa3.

Referring to FIG. 10G, the fourth source layer SLa4 may be formed. The fourth source layer SLa4 may be formed on the source insulating layer SILa. In an implementation, the fourth source layer SLa4, along with other source layers (e.g., SLa1, SLa2, and SLa3), may form the source structure SSTa.

Referring to FIG. 9, the cover insulating layer 150a may be formed. The cover insulating layer 150a may be formed on the fourth source layer SLa4. The via structures BVa may be formed to penetrate the cover insulating layer 150a and to be connected to the fourth source layer SLa4.

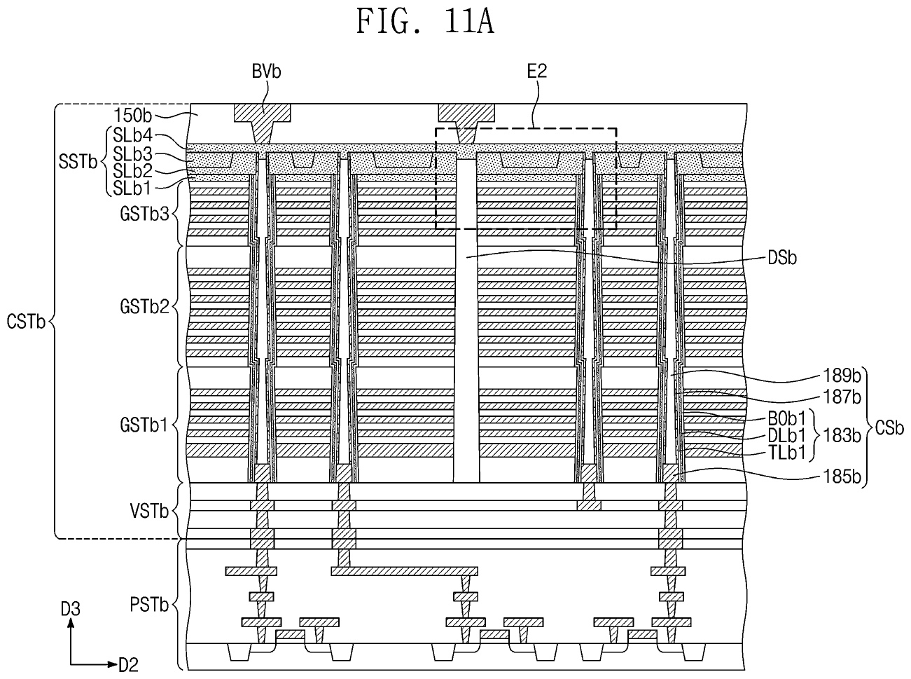

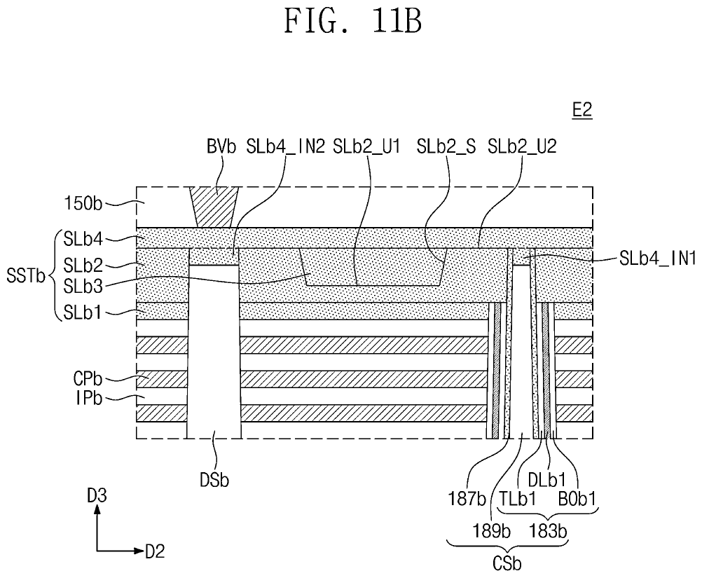

FIG. 11A is a sectional view illustrating an example semiconductor device. FIG. 11B is an enlarged view illustrating a portion ‘E2’ of FIG. 11A.

Referring to FIGS. 11A and 11B, a source structure SSTb may include a first source layer SLb1, a second source layer SLb2, a third source layer SLb3, and a fourth source layer SLb4. The second source layer SLb2 may be disposed on the first source layer SLb1. The third source layer SLb3 may be disposed on the second source layer SLb2. The fourth source layer SLb4 may be disposed on the second source layer SLb2 and the third source layer SLb3.

The second source layer SLb2 may include a first top surface SLb2_U1, a second top surface SLb2_U2, and a side surface SLb2_S. The first top surface SLb2_U1 of the second source layer SLb2 may be in contact with a bottom surface of the third source layer SLb3. The second top surface SLb2_U2 of the second source layer SLb2 may be in contact with the fourth source layer SLb4. The second top surface SLb2_U2 of the second source layer SLb2 may be placed at a level higher than the first top surface SLb2_U1 of the second source layer SLb2. The side surface SLb2_S of the second source layer SLb2 may connect the first and second top surfaces SLb2_U1 and SLb2_U2 of the second source layer SLb2 to each other. The side surface SLb2_S of the second source layer SLb2 may be in contact with a side surface of the third source layer SLb3. The side surface SLb2_S of the second source layer SLb2 may be inclined at an angle.

The third source layer SLb3 may be enclosed by the second source layer SLb2 and the fourth source layer SLb4. A top surface of the third source layer SLb3 may be in contact with the fourth source layer SLb4.

The fourth source layer SLb4 may include a first intervening portion SLb4_IN1 and a second intervening portion SLb4_IN2. The first intervening portion SLb4_IN1 of the fourth source layer SLb4 may be disposed over a first memory channel structure CSb. A bottom surface of the first intervening portion SLb4_IN1 of the fourth source layer SLb4 may be in contact with a top surface of the first insulating capping layer 189b. A side surface of the first intervening portion SLb4_IN1 of the fourth source layer SLb4 may be in contact with an inner side surface of the first channel layer 187b. A bottom surface of the second intervening portion SLb4_IN2 of the fourth source layer SLb4 may be in contact with a top surface of a division structure DSb. A side surface of the second intervening portion SLb4_IN2 of the fourth source layer SLb4 may be in contact with the second source layer SLb2. A thickness of each of the first and second intervening portions SLb4_IN1 and SLb4_IN2 of the fourth source layer SLb4 in the third direction D3 may be smaller than a thickness of the third source layer SLb3 in the third direction D3.

A level of the top surface of the first insulating capping layer 189b may be lower than a level of a top surface of the first channel layer 187b. The level of the top surface of the first insulating capping layer 189b may be higher than a level of the first top surface SLb2_U1 of the second source layer SLb2 and may be lower than a level of the second top surface SLb2_U2.

A level of the top surface of the division structure DSb may be lower than the level of the top surface of the first channel layer 187b. The level of the top surface of the division structure DSb may be higher than the level of the first top surface SLb2_U1 of the second source layer SLb2 and may be lower than the level of the second top surface SLb2_U2.

The second top surface SLb2_U2 of the second source layer SLb2, the top surface of the third source layer SLb3, and the top surface of the first channel layer 187b may be coplanar with each other. In an implementation, the second top surface SLb2_U2 of the second source layer SLb2, the top surface of the third source layer SLb3, and the top surface of the first channel layer 187b may be placed at substantially the same level.

In an example semiconductor device, the fourth source layer SLb4 may include the first intervening portion SLb4_IN1. Due to the first intervening portion SLb4_IN1, a contact area between the first channel layer 187b and the fourth source layer SLb4 may be increased, and this may allow for easy diffusion of electrons or holes. By virtue of the easy diffusion of electrons or holes, the electrical characteristics of the semiconductor device may be improved.

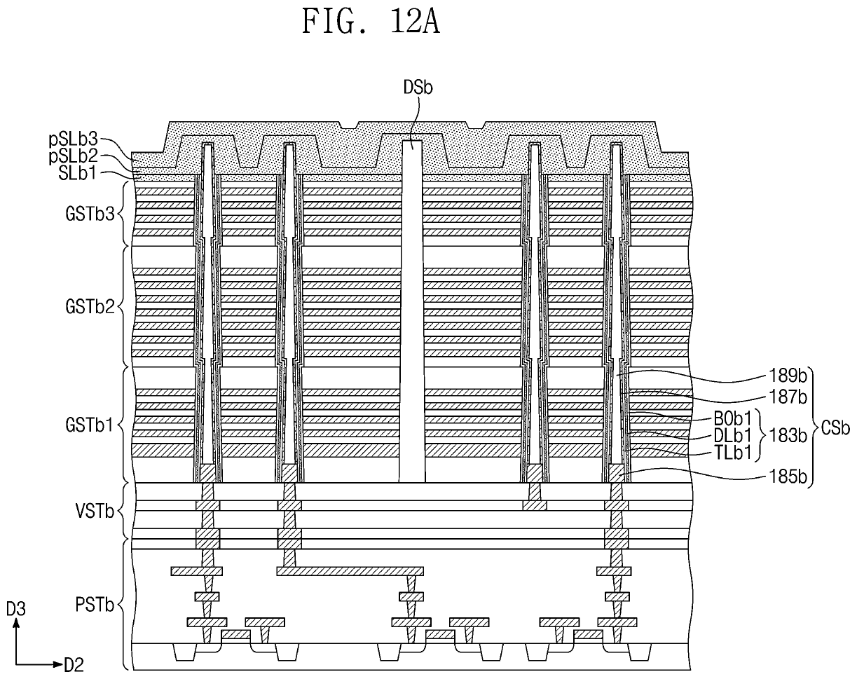

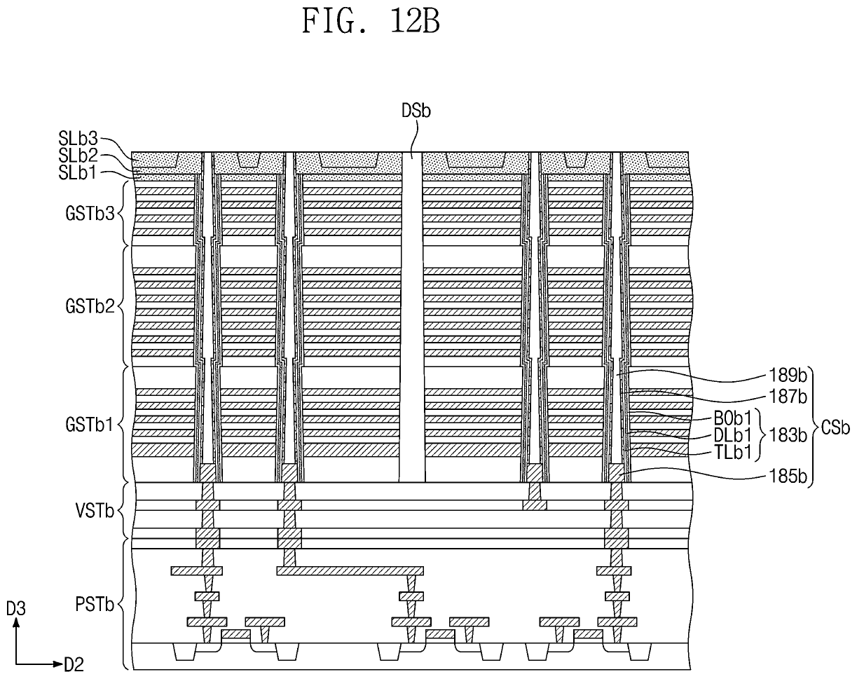

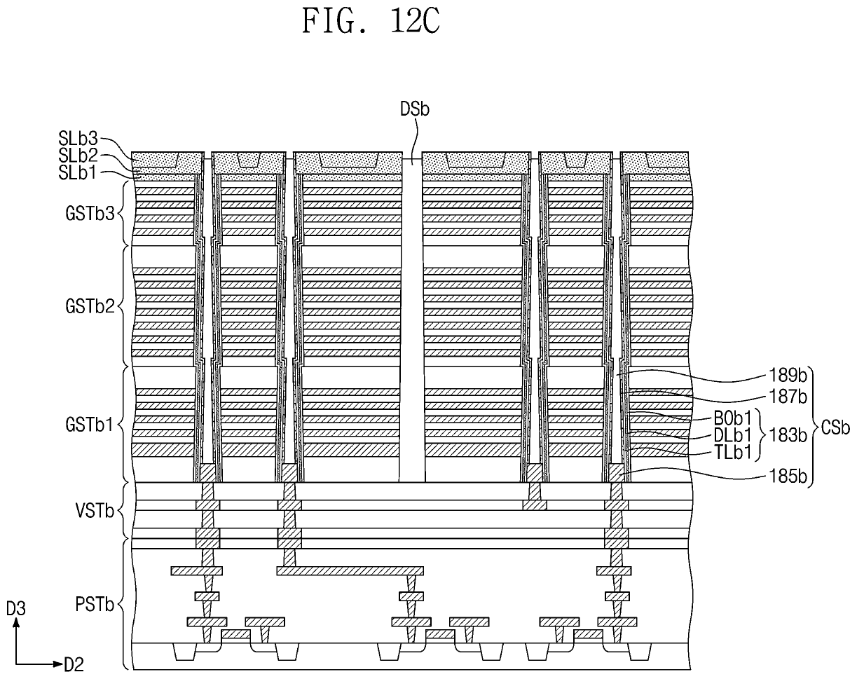

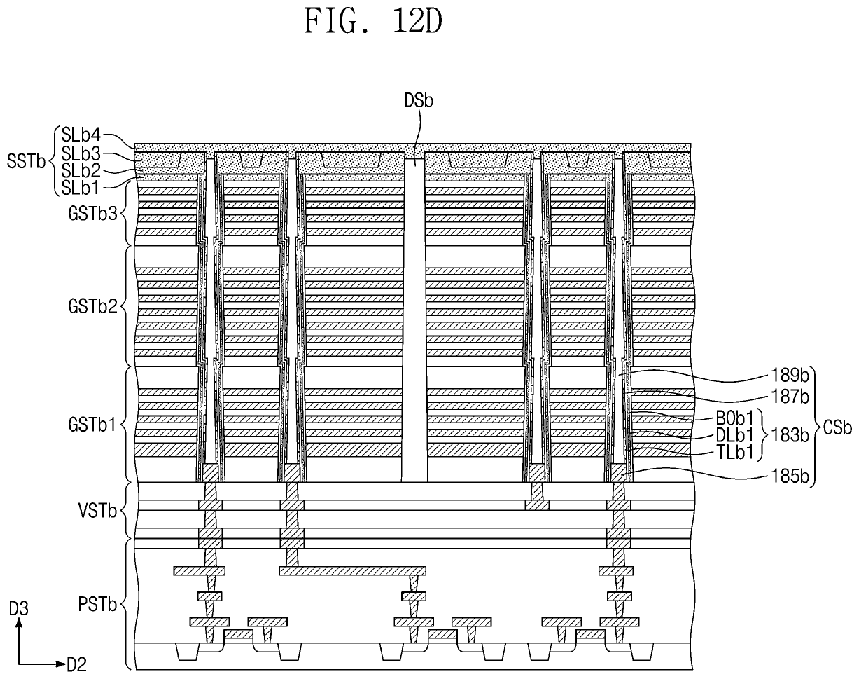

FIGS. 12A, 12B, 12C, and 12D are sectional views illustrating an example method of fabricating a semiconductor device. FIGS. 12A, 12B, 12C, and 12D illustrate a portion of the semiconductor device corresponding to FIG. 11A.

Referring to FIG. 12A, a peripheral circuit structure PSTb, a lower interconnection structure VSTb, a first gate stack GSTb1, a second gate stack GSTb2, a third gate stack GSTb3, first memory channel structures CSb, a division structure DSb, a first source layer SLb1, and a preliminary second source layer pSLb2 may be formed, similar to the implementation of FIGS. 10A, 10B, and 10C.

A preliminary third source layer pSLb3 may be formed. The preliminary third source layer pSLb3 may be formed on the preliminary second source layer pSLb2.

Referring to FIG. 12B, a portion of the preliminary second source layer pSLb2, a portion of the preliminary third source layer pSLb3, a portion of the first channel layer 187b, a portion of the first insulating capping layer 189b, and a portion of the division structure DSb may be removed. The partial removal of the preliminary second source layer pSLb2, the preliminary third source layer pSLb3, the first channel layer 187b, the first insulating capping layer 189b, and the division structure DSb may be performed to expose the top surface of the first channel layer 187b, the top surface of the first insulating capping layer 189b, and the top surface of the division structure DSb. The partially-removed preliminary second source layer pSLb2 may be defined as the second source layer SLb2. The partially-removed preliminary third source layer pSLb3 may be defined as the third source layer SLb3. In an implementation, the portion of the preliminary second source layer pSLb2, the portion of the preliminary third source layer pSLb3, the portion of the first channel layer 187b, the portion of the first insulating capping layer 189b, and the portion of the division structure DSb may be removed by a chemical-mechanical polishing process.

Referring to FIG. 12C, an upper portion of the first insulating capping layer 189b may be removed. The upper portion of the first insulating capping layer 189b may be removed to expose the inner side surface of the first channel layer 187b. In an implementation, the upper portion of the first insulating capping layer 189b may be removed using a wet etching process.

Referring to FIG. 12D, the fourth source layer SLb4 may be formed. The fourth source layer SLb4 may be formed on the second source layer SLb2, the third source layer SLb3, the first channel layer 187b, the top surface of the first insulating capping layer 189b, and the top surface of the division structure DSb. In an implementation, the fourth source layer SLb4, along with other source layers (e.g., SLb1, SLb2, and SLb3), may form the source structure SSTb.

Referring to FIG. 11A, a cover insulating layer 150b may be formed. The cover insulating layer 150b may be formed on the fourth source layer SLb4. Via structures BVb, which are connected to the fourth source layer SLb4, may be formed to penetrate the cover insulating layer 150b.

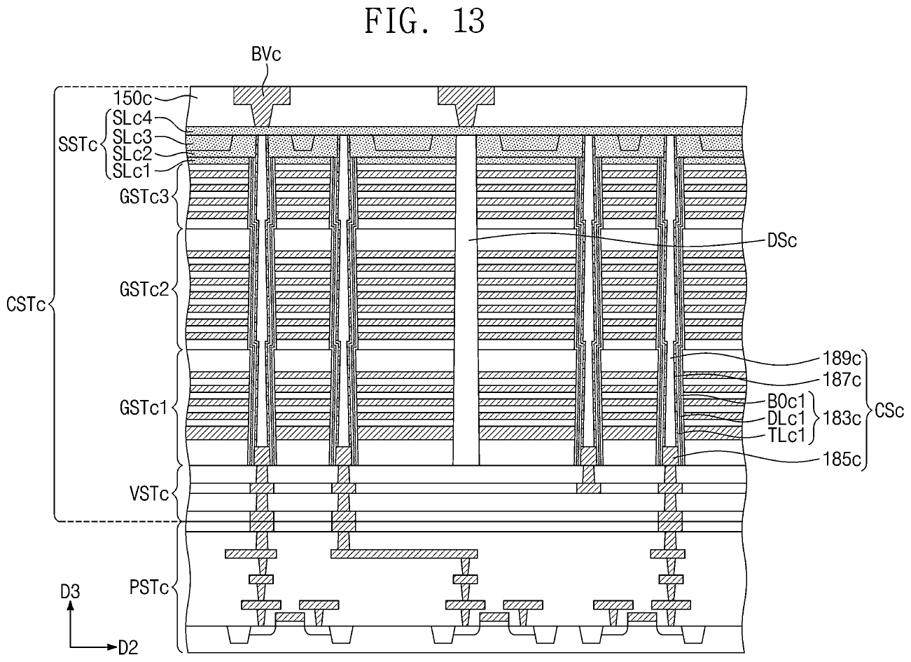

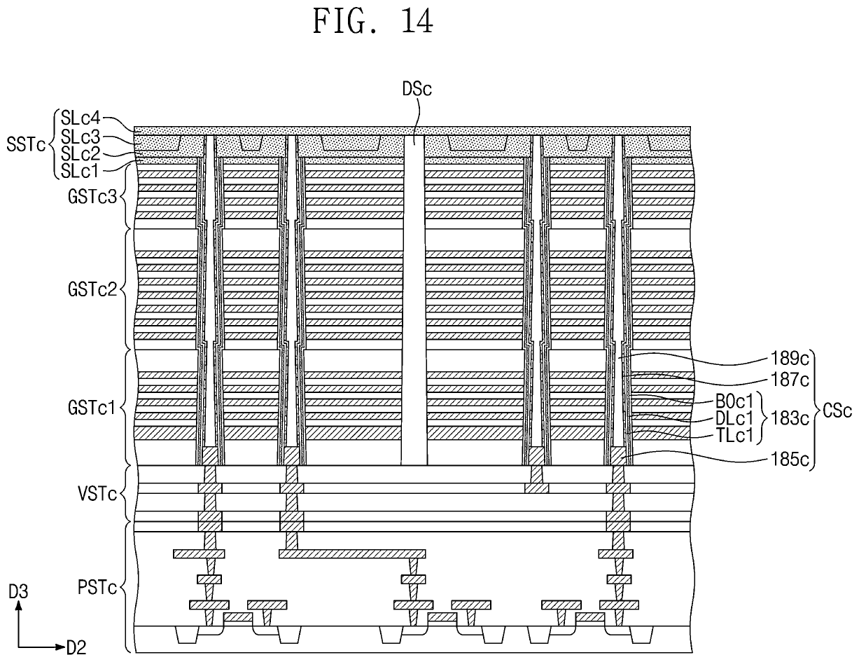

FIG. 13 is a sectional view illustrating an example semiconductor device.

Referring to FIG. 13, the semiconductor device may include a second source layer SLc2, a third source layer SLc3, a first channel layer 187c, a first insulating capping layer 189c, and a division structure DSc whose top surfaces are coplanar with each other. In an implementation, the top surfaces of the second source layer SLc2, the third source layer SLc3, the first channel layer 187c, the first insulating capping layer 189c, and the division structure DSc may be placed at substantially the same level.

FIG. 14 is a sectional view illustrating a method of fabricating a semiconductor device. FIG. 14 illustrates a portion of the semiconductor device corresponding to FIG. 13.

Referring to FIG. 14, a peripheral circuit structure PSTc, a lower interconnection structure VSTc, a first gate stack GSTc1, a second gate stack GSTc2, a third gate stack GSTc3, a first memory channel structures CSc, a division structure DSc, a first source layer SLc1, a second source layer SLc2, and a third source layer SLc3 may be formed, similar to the implementations of FIGS. 10A, 10B, 10C, 12A, and 12B.

A fourth source layer SLc4 may be formed. The fourth source layer SLc4 may be formed on the second source layer SLc2, the third source layer SLc3, a top surface of the first channel layer 187c, a top surface of the first insulating capping layer 189c, and a top surface of the division structure DSc. In an implementation, the fourth source layer SLc4, along with other source layers (e.g., SLc1, SLc2, and SLc3), may form a source structure SSTc.

Referring to FIG. 13, a cover insulating layer 150c may be formed. The cover insulating layer 150c may be formed on the fourth source layer SLc4. Via structures BVc, which are connected to the fourth source layer SLc4, may be formed to penetrate the cover insulating layer 150c.

In a semiconductor device and an electronic system including the same, a second source layer may prevent impurities, which are included in first and third source layers, from being excessively diffused, and thus, the reliability characteristics of the semiconductor device may be improved.

In a semiconductor device and an electronic system including the same, the second source layer may include the intervening portion which is in contact with the first source layer, and this may make it possible to improve the electrical characteristics of the semiconductor device.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While example implementations of have been particularly shown and described, it will be understood by one of ordinary skill in the art that variations in form and detail may be made therein without departing from the spirit and scope of the attached claims.

What is claimed is:

1. A semiconductor device, comprising:
a gate stack with alternating conductive patterns and insulating patterns;
a first memory channel structure including (i) a first channel layer enclosed by the gate stack and (ii) a first memory layer enclosing the first channel layer; and
a source structure electrically connected to the first channel layer,
wherein the source structure comprises a first source layer on the gate stack, a second source layer on the first source layer, and a third source layer on the second source layer,
wherein the first channel layer is spaced apart from the first and third source layers and is in contact with the second source layer,
wherein the first source layer contains impurities of a first conductivity type at a first concentration,
wherein the second source layer contains impurities of the first conductivity type at a second concentration
wherein the third source layer contains impurities of a second conductivity type that is different from the first conductivity type, and
wherein the first concentration is higher than the second concentration.

2. The semiconductor device of claim 1, wherein a level of a top surface of the first memory layer is lower than a level of a bottom surface of the first source layer.

3. The semiconductor device of claim 1, wherein the first memory layer comprises:
a tunnel insulating layer enclosing the channel layer;
a data storing layer enclosing the tunnel insulating layer; and
a blocking layer enclosing the data storing layer,
wherein the tunnel insulating layer, the data storing layer, and the blocking layer have top surfaces located at a level lower than a top surface of the first source layer.

4. The semiconductor device of claim 1, wherein the source structure comprises a doped region including a portion of the first source layer and a portion of the second source layer,
wherein the third source layer contains impurities of the second conductivity type at a third concentration,
wherein the doped region contains impurities of the second conductivity type at a fourth concentration, and
wherein the third concentration is higher than the fourth concentration.

5. The semiconductor device of claim 1, further comprising a second memory channel structure extending through the gate stack,
wherein the second memory channel structure comprises (i) a second channel layer enclosed by the gate stack and (ii) a second memory layer enclosing the second channel layer, and
wherein a level of a top surface of the second memory layer is lower than a level of a top surface of the first source layer.

6. The semiconductor device of claim 5, wherein the second source layer is spaced apart from the second memory channel structure.

7. The semiconductor device of claim 6, further comprising:
a first barrier layer in contact with the third source layer; and
a second barrier layer in contact with the first source layer and the second memory channel structure,
wherein the first source layer comprises an exposed surface that is exposed between the first barrier layer and the second barrier layer.

8. The semiconductor device of claim 5, wherein the second source layer is in contact with the top surface of the second memory layer and the second channel layer, and
wherein the third source layer is spaced apart from the second memory channel structure.

9. The semiconductor device of claim 8, further comprising:
a first barrier layer in contact with the third source layer; and
a second barrier layer in contact with the second source layer,
wherein the second source layer comprises an exposed surface that is exposed between the first barrier layer and the second barrier layer.

10. The semiconductor device of claim 1, further comprising a via structure that is in contact with the second top surface of the source structure.

11. The semiconductor device of claim 1, wherein the insulating patterns comprises an upper insulating pattern, the upper insulating pattern being an uppermost one of the insulating patterns, and
wherein a level of a top surface of the first memory layer is higher than a level of a top surface of the upper insulating pattern.

12. The semiconductor device of claim 1, wherein a top surface of the first memory layer is coplanar with a top surface of the first source layer.

13. A semiconductor device, comprising:
a gate stack with alternating conductive patterns and insulating patterns;
a channel layer enclosed by the gate stack;
a memory layer enclosing the channel layer; and
a source structure electrically connected to the channel layer,
wherein the source structure comprises a first source layer on the gate stack, a second source layer on the first source layer, and a third source layer on the second source layer, and
wherein a level of a top surface of the memory layer is lower than a level of a top surface of the first source layer and is higher than a level of a bottom surface of the first source layer.

14. The semiconductor device of claim 13, wherein the first source layer contains impurities of a first conductivity type at a first concentration,
wherein the second source layer contains impurities of the first conductivity type at a second concentration,
wherein the third source layer contains impurities of a second conductivity type that is different from the first conductivity type, and
wherein the first concentration is higher than the second concentration.

15. The semiconductor device of claim 13, wherein the second source layer is in contact with the first source layer, the top surface of the memory layer, and the channel layer.

16. The semiconductor device of claim 13, wherein the second source layer comprises:
a first top surface;
a second top surface placed at a level higher than the first top surface; and
a side surface connecting the first top surface with the second top surface,
wherein the third source layer comprises:
a first top surface on the first top surface of the second source layer;
a second top surface on the second top surface of the second source layer; and
a side surface on the side surface of the second source layer,
wherein the side surface of each of the second and third source layers has a curved shape.

17. The semiconductor device of claim 16, further comprising a barrier layer in contact with the third source layer,
wherein the side surface of the second source layer and the side surface of the third source layer are convex toward the barrier layer.

18. The semiconductor device of claim 13, wherein the memory layer is in contact with a side surface of the first source layer.

19. A semiconductor device, comprising:
a main substrate;
a semiconductor device on the main substrate; and
a controller on the main substrate and electrically connected to the semiconductor device,
wherein the semiconductor device comprises:
a peripheral circuit structure; and
a memory cell structure on the peripheral circuit structure,
wherein the memory cell structure comprises:
a gate stack with alternating conductive patterns and insulating patterns;
a channel layer extending through the gate stack;
a memory layer enclosing the channel layer; and
a source structure on the gate stack,
wherein the source structure comprises a first source layer on the gate stack, a second source layer on the first source layer, and a third source layer on the second source layer,
wherein the channel layer is spaced apart from the first and third source layers and is in contact with the second source layer,
wherein the second source layer comprises an intervening portion interposed between the channel layer and the first source layer, and
wherein a thickness of the intervening portion is smaller than a thickness of the first source layer.

20. The semiconductor device of claim 19, wherein the intervening portion is in contact with a side surface of the channel layer, a side surface of the first source layer, and a top surface of the memory layer.
